(19) United States
(12) Patent Application Publication
(10) Pub. No.: US 2005/0115671 A1
(43) Pub. Date: Jun. 2, 2005

(54) Substrate treating apparatus and substrate treating method

(75) Inventor: Hiroyuki Araki, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 10/998,843

(22) Filed: Nov. 29, 2004

(30) Foreign Application Priority Data
Dec. 2, 2003 (JP) 2003-403575
Mar. 26, 2004 (JP) 2004-093487

(51) Int. Cl. H01L 21/306

(52) U.S. Cl. 156/345.12; 216/52

(57) ABSTRACT

A substrate treating apparatus includes at least two types of treatment units, and a substrate carrying mechanism for carrying a substrate into/out of at least the two types of treatment units. At least the two types of treatment units are selected out of a chemical liquid treatment unit for supplying a chemical liquid to the substrate, a scrubbing unit for scrubbing a surface of the substrate, a polymer removal unit for supplying a polymer removal liquid to the substrate, a peripheral end surface treatment unit for supplying a treatment liquid to an area including the whole of one surface and a peripheral end surface of the substrate, and a gas phase treatment unit for supplying a vapor to the substrate.

### BACKGROUND OF THE INVENTION

1. Field of the Invention

The present invention relates to a substrate treating apparatus and a substrate treating method for treating various types of substrates represented by a semiconductor wafer, a glass substrate for a liquid crystal display device, a glass substrate for a plasma display, a substrate for an optical disk, a substrate for a magnetic disk, a substrate for a magneto-optic disk, and a substrate for a photomask.

2. Description of Related Art

In the steps of fabricating a semiconductor device, cleaning treatment for cleaning a surface of a semiconductor wafer, etching treatment for removing an unnecessary thin film from the surface of the semiconductor wafer, and so on are repeatedly performed. Today when a semiconductor product line is diversified, and a fabrication process is finely divided, a higher-level cleaning technique has been required for a substrate treating apparatus used for cleaning the semiconductor wafer.

The substrate treating apparatus for cleaning a substrate such as a semiconductor wafer is roughly classified into a sheeting apparatus for treating substrates one at a time (single substrate processing) and a batch type apparatus for together treating a plurality of (e.g., 50) substrates. In the batch-type substrate treating apparatus, the plurality of substrates are together dipped in a treatment liquid tank and treated, so that the transition of contamination from a non-device formation surface to a device formation surface of the substrate and the transition of contamination between the substrates cannot be avoided. When an attempt is made to circulate and reuse a treatment liquid in the treatment liquid tank so as to achieve cost reduction, contamination is stored in the treatment liquid, so that the cleanness of the substrate is gradually degraded.

Such a problem does not arise in the sheeting substrate treating apparatus, so that high cleanness can be uniformly obtained for a plurality of substrates. However, all sheeting substrate treating apparatuses conventionally provided are for a single application such as an application for removing particles, an application for pretreatment before diffusion or before film formation, an application for removing a resist residue (a polymer) after dry etching or ashing, an application for cleaning in the vicinity of one surface and a peripheral end surface of a substrate, and an application for gas phase etching. Consequently, a plurality of different types of treating apparatuses must be installed in a clean room depending on a process to be executed. Therefore, the sheeting substrate treating apparatus is suitable for mass production but is unsuitable for limited production of diversified products.

In the sheeting substrate treating apparatus, one surface of the substrate can be subjected to highly uniform treatment. However, it is difficult to subject both surfaces of the substrate to suitable cleaning treatment depending on the state of each of the surfaces. Therefore, it is difficult to obtain high cleanness for both the surfaces.

### SUMMARY OF THE INVENTION

An object of the present invention is to provide a substrate treating apparatus and a substrate treating method capable of subjecting a substrate to a plurality of types of treatments (particularly, cleaning treatment) and therefore, capable of satisfactorily coping with limited production of diversified products.

Another object of the present invention is to provide a substrate treating apparatus and a substrate treating method capable of subjecting both surfaces of a substrate to good treatment (particularly, cleaning treatment).

A substrate treating apparatus according to an aspect of the present invention comprises at least two types of treatment units, and a substrate carrying mechanism for carrying a substrate into/out of at least the two types of treatment units. At least the two types of treatment units are selected out of a chemical liquid treatment unit for holding and rotating a substrate by a substrate holding and rotating mechanism as well as supplying a chemical liquid from a chemical liquid nozzle to the substrate to treat the substrate, a scrubbing unit for holding and rotating a substrate by a substrate holding and rotating mechanism to supply deionized water to the substrate as well as scrubbing a surface of the substrate with a scrub brush, a polymer removal unit for holding and rotating a substrate by a substrate holding and rotating mechanism as well as supplying a polymer removal liquid to the substrate to remove a residue on the substrate, a peripheral end surface treatment unit for holding and rotating a substrate by a substrate holding and rotating mechanism as well as supplying a treatment liquid to an area including the whole of one surface and a peripheral end surface of the substrate so as to selectively remove an unnecessary material in the area, and a gas phase treatment unit for supplying a vapor including a chemical liquid and a vapor including a chemical gas to a substrate held in a substrate holding mechanism to treat the substrate.

By this configuration, at least the two types of treatment units, together with the substrate carrying mechanism, are provided in the one substrate treating apparatus. Accordingly, the substrate can be continuously subjected to the two or more types of treatments by the one substrate treating apparatus. This makes it possible to satisfactorily cope with limited production of diversified products.

The chemical liquid treatment unit is a sheeting or single-substrate-processing type treatment unit comprising the substrate holding and rotating mechanism for holding and rotating substrates, and the chemical liquid nozzle for supplying a chemical liquid to the substrate to be treated which is held and rotated by the substrate holding and rotating mechanism, for treating the substrates one at a time. The chemical liquid treatment unit may further comprise a rinsing liquid nozzle for supplying a rinsing liquid (deionized water) for eliminating the chemical liquid from the substrate.

The scrubbing unit is a sheeting or single-substrate-processing type treatment unit comprising the substrate holding and rotating mechanism for holding and rotating a substrate, and the scrub brush for scrubbing a surface of the substrate which is held and rotated by the substrate holding and rotating mechanism. The scrubbing unit may further comprise a protective liquid nozzle for supplying a protective liquid (e.g., deionized water) to a surface (e.g., a lower surface) opposite to a surface to be treated of the substrate (e.g., an upper surface of the substrate in a case where the substrate is held in a horizontal posture).

The scrubbing unit may further comprise a droplet jet supply section for supplying a jet of droplets of the treatment liquid to the surface of the substrate. By cleaning the surface of the substrate by the jet of droplets, foreign matter on the surface of the substrate can be effectively removed while restraining the destruction of a micropattern (a gate pattern, etc.) on the surface of the substrate. The droplet jet supply section may be a two-fluid spray nozzle for mixing a liquid and a gas to form the jet of droplets.

The two-fluid spray nozzle has a casing having a liquid inlet, a gas inlet, and a discharge outlet. Used as such a two-fluid spray nozzle may be one of an internal mixing type such that a mixture of a gas and a liquid is produced in a mixing chamber in the casing to spray droplets from the discharge outlet and one of an external mixing type such that a mixture of a gas and a liquid is produced outside the casing in the vicinity of the discharge outlet to form droplets outside the casing. The two-fluid spray nozzle of either type may be used.

It is preferable that the two-fluid spray nozzle is constructed in the form of a scan nozzle which is movable in at least a range from the center to the peripheral end of the substrate. Alternatively, a range where the scan nozzle moves may be a range from the peripheral end of the substrate to the other peripheral end through the center thereof (a substantial diameter range of the substrate). In this case, by spraying droplets to the surface of the substrate in at least the step of moving the two-fluid spray nozzle from the center to the peripheral end of the substrate, thereby allowing foreign matter on the surface of the substrate (an unnecessary material separated from the surface of the substrate (a resist residue, etc.)) to be effectively eliminated outward from the surface of the substrate.

The polymer removal unit is a sheeting or single-substrate-processing type treatment unit, and may comprise a substrate holding and rotating mechanism for holding and rotating the substrate and a polymer removal liquid nozzle for supplying a polymer removal liquid to the surface of the substrate held in the substrate holding and rotating mechanism. The polymer removal unit may further comprise a rinsing liquid nozzle for supplying a rinsing liquid (deionized water) toward the substrate held in the substrate holding and rotating mechanism. The polymer removal unit may further comprise a droplet jet supply section for supplying a jet of droplets of the treatment liquid toward the surface of the substrate held in the substrate holding and rotating mechanism. The droplet jet supply section may be composed either of the above-mentioned two-fluid spray nozzle. The polymer removal unit may further comprise a shielding member having a substrate opposite surface opposed to the surface of the substrate to be treated and a shielding member movement section for bringing the shielding member nearer to/away from the surface of the substrate.

The peripheral end surface treatment unit is a sheeting treatment unit, and may comprise the substrate holding and rotating mechanism for holding and rotating the substrate almost horizontally, a treatment liquid supply section for supplying a treatment liquid for cleaning to a lower surface of the substrate held in the substrate holding and rotating mechanism, a shielding member having a substrate opposite surface opposed to an upper surface of the substrate held in the substrate holding and rotating mechanism, and a shielding member moving mechanism for bringing the shielding member nearer to/away from the upper surface of the substrate held in the substrate holding and rotating mechanism. It is preferable that the substrate holding and rotating mechanism comprises a plurality of clamp members for interposing the peripheral end surface of the substrate, and the substrate treating apparatus further comprises a clamp member driving mechanism for releasing or canceling the clamping of the substrate by the plurality of clamp members while the substrate is being rotated by the substrate holding and rotating mechanism. Further, it is preferable that the substrate holding and rotating mechanism comprises two groups of clamp members each having at least two clamp members for clamping the peripheral end surface of the substrate, and there is provided two clamp member driving mechanisms for independently driving the two groups of clamp members, to allow switching from the clamping of the substrate by one of the two groups of clamp members (a first clamping state) to the clamping of the substrate by the other one of the two groups of clamp members (a second clamping state) while the substrate is being rotated by the substrate holding and rotating mechanism by the actions of the two clamp member driving mechanisms. It is preferable that in the step of the switching, the operations of the two clamp member driving mechanisms are controlled such that an intermediate state where the substrate is clamped by both the groups of clamp members occurs.

The gas phase treatment unit is a sheeting or single-substrate-processing type treatment unit comprising the substrate holding mechanism and a vapor supply section for supplying a vapor including a chemical liquid or a vapor including a chemical gas to the substrate held in the substrate holding mechanism. It is preferable that the gas phase treatment unit further comprises a substrate temperature adjustment section for adjusting the temperature of the substrate held in the substrate holding mechanism to a predetermined temperature.

A chemical liquid used for producing the vapor in the gas phase treatment unit may be a chemical liquid containing an acid such as a hydrofluoric acid, a nitric acid, an acetic acid, a hydrochloric acid, a sulfuric acid, an oxalic acid, or a citric acid or a chemical liquid containing an alkali such as ammonia. Further, the chemical liquid may be a mixed liquid obtained by adding an oxidizing agent such as a hydrogen peroxide solution or ozone or an organic solvent such as methanol to the oxide or the alkali.

In the gas phase treatment unit, the chemical gas used for producing the vapor may be a gas containing any one of an anhydrous hydrofluoric acid gas, an ammonia gas, a hydrogen chloride gas, a nitrogen dioxide gas, and an SO₃ gas, or a mixed gas of two or more types of the gases. The vapor including the chemical gas may be a mixture of the chemical gas and a vapor or a mixture of the chemical gas and a vapor including an organic solvent such as methanol, or a vapor obtained by further mixing the mixture with the carrier gas such as an inert gas.

It is preferable that the substrate treating apparatus further comprises a reversing unit for reversing the front and back surfaces of the substrate carried by the substrate carrying mechanism from one of at least the two types of treatment units.

By this configuration, the front and back surfaces of the substrate can be reversed between the two types of treatment units, thereby making it possible to subject each of the front and the back surfaces of the substrate to treatment which differs between the two types of treatment units. Consequently, both the surfaces of the substrate can be respectively subjected to most suitable treatment. More specifically, after the treatment for one of the surfaces of the substrate is completed by the given treatment unit, the substrate is carried into the reversing unit to reverse the substrate, the substrate which has been reversed is carried into the other treatment unit to treat the substrate, thereby making it possible to treat the other surface of the substrate. Consequently, treatment suitable for each of the surfaces of the substrate can be performed, thereby making it possible to satisfactorily treat both the surfaces of the substrate.

When at least the two types of treatment units comprise the scrubbing unit, it is preferable that the scrubbing unit scrubs the surface of the substrate which has been reversed by the reversing unit.

By this configuration, after the treatment for one of the surfaces (e.g., a device formation surface) is completed by the given treatment unit (a chemical liquid treatment unit, a polymer removal unit, a peripheral end surface treatment unit, or a gas phase treatment unit), the substrate is carried into the reversing unit to reverse the substrate, and the substrate which has been reversed is carried into the scrubbing unit to treat the substrate, thereby making it possible to subject the other surface of the substrate (e.g., a non-device formation surface) to scrubbing treatment. Consequently, the one surface of the substrate (e.g., the device formation surface) is satisfactorily treated, and the other surface of the substrate (the non-device formation surface) can be satisfactorily scrubbed, that is, both the surfaces of the substrate can be satisfactorily treated.

It is preferable that at least the two types of treatment units comprise the chemical liquid treatment unit and the scrubbing unit. By this configuration, the substrate can be subjected to the chemical liquid treatment and the scrubbing treatment within one substrate treating apparatus. More specifically, for example, the one surface of the substrate (e.g., the device formation surface) can be subjected to chemical liquid treatment for cleaning before diffusion or cleaning before film formation in the chemical liquid treatment unit, and the other surface of the substrate (e.g., the non-device formation surface) can be then subjected to scrubbing treatment (e.g., cleaning treatment for cleaning an electrostatic chuck trace) in the scrubbing unit. If the front and back surfaces of the substrate are reversed by the reversing unit before the substrate is carried into the scrubbing unit, the treatment for the other surface in the scrubbing unit can be satisfactorily performed.

In the scrubbing unit, when the substrate is held in a substantially horizontal posture by the substrate holding and rotating mechanism, and the upper surface of the substrate (e.g., the non-device formation surface) is subjected to scrubbing treatment, it is preferable that a protective liquid for protecting the lower surface of the substrate (e.g., the device formation surface) is supplied to the lower surface from a protective liquid nozzle. Consequently, it is possible to protect the lower surface of the substrate and to prevent a contaminant from detouring from the upper surface to the lower surface of the substrate.

The chemical liquid treatment in the chemical liquid treatment unit may comprise etching treatment for supplying an etchant containing a chemical liquid such as a hydrofluoric acid to the surface of the substrate from the chemical liquid nozzle, to etch the substrate. Alternatively, the chemical liquid treatment may comprise chemical liquid cleaning treatment for supplying a cleaning liquid containing a chemical liquid such as a hydrofluoric acid, an SC1 (a mixture of ammonia and a hydrogen peroxide solution) or SC2 (a mixture of a sulfuric acid and a hydrogen peroxide solution), to remove foreign matter on the surface of the substrate.

The chemical liquid treatment may comprise resist stripping treatment for supplying a resist stripping liquid as one type of chemical liquid. The chemical liquid treatment may comprise polymer removal treatment for supplying a polymer removal liquid serving as one type of chemical liquid to the surface of the substrate from the chemical liquid nozzle and removing a resist residue (a polymer) remaining on the surface of the substrate after the resist stripping treatment.

The resist stripping liquid may be a mixture of a sulfuric acid and a hydrogen peroxide solution.

Usable as the polymer removal liquid is at least one of a liquid containing an organic alkaline solution, a liquid containing an organic acid, a liquid containing an inorganic acid, and a liquid containing ammon fluorides. Examples of the liquid containing an organic alkaline solution include a liquid containing at least one of DMF (dimethylformamide), DMSO (dimethylsulfoxide), hydroxylamine, and choline. Examples of the liquid containing an organic acid include a liquid containing at least one of a citric acid, an oxalic acid, an iminodi acid, and a succinic acid. Examples of the liquid containing an inorganic acid include a liquid containing at least one of a hydrofluoric acid and a phosphoric acid. In addition thereto, examples of the polymer removal liquid include a liquid containing at least one of 1-methyl-2-pyrrolidone, tetrahydrothiophene 1.1-dioxide, isopropanolamine, monoethanolamine, 2-(2-aminoethoxy)ethanol, catechol, N-methyl pyrrolidone, aromatic diol, perflene, and phenol. More specifically, examples of the polymer removal liquid include at least one of a mixture of 1-methyl-2-pyrrolidone, tetrahydrothiophene 1.1-dioxide, and isopropanolamine, a mixture of dimethyl sulfoxide and monoethanolamine, a mixture of 2-(2-aminoethoxy)ethanol, hydroxylamine, and catechol, a mixture of 2-(2-aminoethoxy) ethanol and N-methyl pyrrolidone, a mixture of monoethanolamine, water, and aromatic diol, and a mixture of perflene and phenol. The other examples of the polymer removal liquid include a liquid containing at least one of amines such as triethanolamine, and pentamethyl diethylenetriamine, propylene glycol, dipropylene glycol monomethyl ether, etc.

The chemical liquid nozzle for supplying the polymer removal liquid may be a normal straight nozzle (normal nozzle) However, it is preferable that the chemical liquid nozzle is composed of a two-fluid spray nozzle, as described above. Consequently, chemical resist residue removal treatment using the polymer removal liquid can be performed under assist due to a physical force.

At least the two types of treatment units may comprise the chemical liquid treatment unit and the polymer removal unit. By this configuration, the substrate can be subjected to the chemical liquid treatment and the polymer removal treatment within one substrate treating apparatus.

More specifically, when the chemical liquid nozzle in the chemical liquid treatment unit comprises a nozzle for supplying a resist stripping liquid for stripping the resist film on the surface of the substrate which is held by the substrate holding and rotating mechanism (it may be a straight nozzle or a two-fluid spray nozzle), resist stripping treatment and the subsequent polymer removal treatment can be performed within one substrate treating apparatus.

The resist stripping treatment and the polymer removal treatment are performed by separate treatment units (separate treatment chambers) within one substrate treating apparatus, thereby making it possible to prevent such recontamination that a resist which has been stripped once from the substrate by the resist stripping treatment adheres to the inner wall of the treatment chamber, and falls down to adhere to the substrate again. Even when an acidic (inorganic) chemical liquid such as a mixture of a hydrofluoric acid and a hydrogen peroxide solution is used for the resist stripping treatment, and an organic chemical liquid is used for the polymer removal treatment, cross contamination of the chemical liquids can be restrained or prevented. Consequently, the respective chemical liquids (particularly, the polymer removal liquid) can be recovered and reused while restraining the contamination thereof.

Furthermore, at least the two types of treatment units may comprise the scrubbing unit and the polymer removal unit. The substrate can be subjected to the polymer removal treatment and the scrubbing treatment within one substrate treating apparatus. More specifically, the one surface of the substrate (e.g., the device formation surface) can be subjected to the above-mentioned polymer removal treatment in the polymer removal unit, and the other surface (e.g., the non-device formation surface) of the substrate can be then subjected to scrubbing treatment (e.g., cleaning treatment for cleaning an electrostatic chuck trace) in the scrubbing unit, for example. If the surface and the reverse surface of the substrate are reversed by the reversing unit before the substrate is carried into the scrubbing unit, the treatment for the other surface in the scrubbing unit can be satisfactorily performed.

The polymer removal treatment in the polymer removal unit may comprise the step of supplying a polymer removal liquid to the substrate from the polymer liquid supply nozzle, the step of supplying a rinsing liquid to the substrate from the rinsing liquid supply nozzle to eliminate the polymer removal liquid on the substrate, and the step of supplying a jet of droplets of deionized water to the substrate by the droplet jet supply section to precisely eliminate a resist residue within a micropattern on the surface of the substrate.

At least the two types of treatment units may comprise the polymer removal unit and the peripheral end surface treatment unit. By this configuration, the substrate can be subjected to the polymer removal treatment and the peripheral end surface treatment within one substrate treating apparatus. More specifically, the one surface of the substrate (e.g., the device formation surface) can be subjected to the above-mentioned polymer removal treatment in the polymer removal unit, and an area including the other surface (e.g., the non-device formation surface) and a peripheral end surface of the substrate can be then selectively subjected to unnecessary material removal treatment (e.g., cleaning treatment for cleaning an electrostatic chuck trace) in a state where it does not affect the one surface of the substrate in the peripheral end surface treatment unit, for example.

The treatment by the peripheral end surface treatment unit may be treatment for spreading the treatment liquid to an area from the lower surface to the peripheral end surface of the substrate by rotating the substrate with the substrate held almost horizontally by the substrate holding and rotating mechanism as well as supplying the treatment liquid (e.g., a mixture of a hydrofluoric acid and a hydrogen peroxide solution) to the lower surface of the substrate. In this case, the effect of the treatment liquid may be prevented from being exerted on the device formation area on the upper surface (the device formation surface) of the substrate by opposing the substrate opposite surface of the shielding member to the upper surface of the substrate in close proximity thereto or supplying an inert gas (a nitrogen gas, etc.) between the substrate opposite surface and the substrate.

At least the two types of treatment units may comprise the chemical liquid treatment unit and the gas phase treatment unit. By this configuration, the substrate can be subjected to the treatment by the chemical liquid treatment unit and the treatment by the gas phase treatment unit within one substrate treating apparatus.

The treatment by the gas phase treatment unit may be selective gas phase etching treatment for selectively removing a BPSG (Boro-phospho silicate glass) film on the substrate, for example, without substantially affecting an oxide film (e.g., a silicon oxide film) formed on the same substrate. More specifically, good selective etching is allowed by supplying a vapor including a hydrofluoric acid (a hydrofluoric acid vapor) to the substrate as well as keeping the temperature of the substrate at such a temperature that the etching selection ratio of the BPSG film to the oxide film can be made high.

It is preferable that the chemical liquid treatment unit further comprises a droplet jet supply section for supplying a jet of droplets of the treatment liquid to the substrate held in the substrate holding and rotating mechanism. In this case, the treatment by the chemical liquid treatment unit may comprise treatment for supplying a jet of droplets of a treatment liquid (a chemical liquid or deionized water) onto the substrate, to remove a reaction product entering a micropattern on the substrate by the physical action of the jet of droplets, for example. That is, the chemical liquid treatment unit may simultaneously have the function of removing foreign matter on the surface of the substrate by a physical force.

In addition thereto, the treatment by the chemical liquid treatment unit may further comprise treatment for rinsing the surface of the substrate by a rinsing liquid (deionized water) and drying treatment for drying the surface of the substrate after the rinsing treatment.

When the substrate is dried by the chemical liquid treatment unit, the drying treatment may be treatment for bringing the substrate opposite surface of the shielding member nearer to the surface of the substrate as well as rotating the substrate to shake down the droplets on the substrate to dry the substrate in a state where an inert gas (a nitrogen gas, etc.) is supplied between the substrate and the substrate opposite surface. The drying treatment is thus performed in an inert gas atmosphere, thereby making it possible to prevent a water mark from being formed on the surface of the substrate where a hydrophilic portion and a hydrophobic portion are mixed.

A substrate treating method according to an aspect of the present invention comprises at least two steps out of a chemical liquid treating step for supplying a chemical liquid to a substrate which is held and rotated by a substrate holding and rotating mechanism to treat a substrate, a scrubbing step for supplying deionized water to a substrate which is held and rotated by a substrate holding and rotating mechanism as well as scrubbing a surface of the substrate with a scrub brush to remove foreign matter on the surface of the substrate, a polymer removing step for supplying a polymer removal liquid to a substrate which is held and rotated by a substrate holding and rotating mechanism, to remove a residue on the substrate, a peripheral end surface treating step for supplying a treatment liquid to an area including the whole of one of surfaces and a peripheral end surface of a substrate which is held and rotated by a substrate holding and rotating mechanism, to selectively remove an unnecessary material in the area, and a gas phase treating step for supplying a vapor including a chemical liquid or a vapor including a chemical gas to a substrate held in a substrate holding mechanism to treat the substrate.

It is preferable that at least the two steps are continuously carried out through a substrate carrying step for carrying the substrate without accommodating, between the steps, the substrate in an accommodation chamber capable of accommodating a plurality of substrates.

The substrate treating method may further comprise a reversing step for reversing the front and back surfaces of the substrate between at least the two steps.

In this case, it is preferable that the scrubbing step is carried out after the reversing step, to subject a non-device formation surface which is opposite to a device formation surface of the substrate to scrubbing treatment.

At least the two steps may comprise the chemical liquid treating step and the scrubbing step. In this case, it is preferable that the device formation surface of the substrate is subjected to chemical liquid treatment in the chemical liquid treating step, and a non-device formation surface which is opposite to the device formation surface of the substrate is subjected to the scrubbing treatment in the scrubbing step.

At least the two steps may comprise the chemical liquid treating step and the polymer removing step, the chemical liquid may be supplied to the device formation surface of the substrate to perform chemical liquid treatment in the chemical liquid treating step, and the device formation surface of the substrate may be subjected to polymer removal treatment in the polymer removing step.

More specifically, the chemical liquid treating step may comprise the step of supplying a resist stripping liquid as the chemical liquid to the device formation surface of the substrate, to strip the resist film on the device formation surface.

The resist film on the substrate can be striped by such a method, and the treatment for removing the polymer on the substrate can be then performed.

The resist stripping treatment and the polymer removal treatment may be performed by different treatment chambers. Consequently, the resist adhering to the inner wall of the chamber can be prevented from adhering to the substrate again, and the resist stripping liquid and the polymer removal liquid can be prevented from being mixed with each other.

If the resist stripping treatment and the polymer removal treatment are performed in the same treatment chamber, the necessity of carrying the substrate between the treatment chambers between the treatments can be eliminated, thereby making it possible to successively perform the polymer removal treatment without drying the substrate after the resist stripping treatment. More specifically, the polymer removal treatment can be performed by supplying the resist stripping liquid-to the substrate to perform the resist stripping treatment, then supplying a rinsing liquid such as deionized water to the surface of the substrate to replace the resist stripping liquid with the rinsing liquid, and then supplying the polymer removal liquid to the substrate without passing through the drying treatment of the substrate (shaking and drying treatment for shaking down a liquid). Consequently, the surface of the substrate can be subjected to the polymer removal treatment in a wet state from the beginning, thereby allowing the polymer removal efficiency to be improved.

Since the substrate need not be carried between the resist stripping treatment and the polymer removal treatment, it is possible to shorten the overall substrate treatment time period as well as to reduce the number of treatment chambers to miniaturize the substrate treating apparatus.

When the resist stripping treatment and the polymer removal treatment are performed in the same treatment chamber, it is preferable that an inorganic polymer removal liquid (e.g., a mixed liquid of a hydrofluoric acid and deionized water) can be used as a polymer removal liquid. Consequently, an inorganic chemical liquid can be used for both the resist stripping liquid and the polymer removal liquid, thereby making it possible to prevent an inorganic chemical liquid and an organic chemical liquid from being mixed with each other.

At least the two steps may include the scrubbing step and the polymer removing step. The device formation surface of the substrate may be subjected to polymer residue removal treatment in the polymer removing step, and a non-device formation surface which is opposite to the device formation surface of the substrate may be subjected to scrubbing treatment in the scrubbing step.

At least the two steps may include the polymer removing step and the peripheral end surface treating step. The device formation surface of the substrate may be subjected to polymer removal treatment in the polymer removing step, and unnecessary materials on a non-device formation surface which is opposite to the device formation surface and a peripheral end surface of the substrate may be selectively removed in the peripheral end surface treating step.

At least the two steps may include the gas phase treating step and the chemical liquid treating step. The device formation surface of the substrate may be subjected to the gas phase treatment in the gas phase treating step, and may be subjected to the chemical liquid treatment in the chemical liquid treating step.

In the chemical liquid treating step, a jet of droplets of the treatment liquid may be supplied to the device formation surface.

A substrate treating apparatus according to another aspect of the present invention comprises a substrate holding and rotating mechanism for holding and rotating a substrate, a resist stripping liquid nozzle for supplying a resist stripping liquid to a substrate to be treated which is held and rotated by the substrate holding and rotating mechanism, and a polymer removal liquid nozzle for supplying a polymer removal liquid to the substrate to be treated which is held and rotated by the substrate holding and rotating mechanism.

By this configuration, the resist stripping treatment using the resist stripping liquid can be performed in a state where the substrate to be treated is held and rotated by the substrate holding and rotating mechanism, and the polymer removal treatment using the polymer removal liquid can be then performed. Since the substrate need not be carried between the resist stripping treatment and the polymer removal treatment (e.g., carried between treatment chambers), therefore, the substrate need not be dried once after the resist stripping treatment and before the polymer removal treatment. Consequently, the polymer removal treatment can be performed with a wet state after the resist stripping treatment held, thereby allowing the polymer removal treatment to be efficiently performed.

Furthermore, the drying step after the resist stripping treatment can be omitted, thereby allowing the overall substrate treatment time period to be shortened. Further, the number of treatment chambers can be made smaller, so that the substrate treating apparatus can be made smaller in size, as compared with that in a case where the resist stripping treatment and the polymer removal treatment are performed by separate treatment chambers.

It is preferable that after the resist stripping treatment, the substrate held in the substrate holding and rotating mechanism is subjected to the polymer removal treatment after being supplied with the rinsing liquid such as the deionized water from the rinsing liquid nozzle in order to eliminate the resist stripping liquid on the substrate.

It is preferable that the polymer removal liquid nozzle supplies an inorganic polymer removal liquid (e.g., a dilute hydrofluoric acid solution). Consequently, the polymer removal liquid can be an inorganic chemical liquid, similarly to the resist stripping liquid composed of an acid (inorganic) chemical liquid such as a mixture of a hydrofluoric acid and a hydrogen peroxide solution, thereby allowing the mixing of the organic chemical liquid and the inorganic chemical liquid to be restrained.

The resist stripping liquid nozzle may be a straight nozzle or a two-fluid spray nozzle. Similarly, the polymer removal liquid nozzle may be a straight nozzle or a two-fluid spray nozzle.

A substrate treating method according to another aspect of the present invention comprises a substrate holding and rotating step for holding and rotating a substrate by a substrate holding and rotating mechanism arranged in a treatment chamber, a resist stripping step for supplying a resist stripping liquid to the surface of the substrate which is held and rotated in the substrate holding and rotating step, to strip a resist film on the substrate, and a polymer removing step for supplying a polymer removal liquid to a surface of the substrate which is held in the substrate holding and rotating step after the resist stripping step.

It is preferable that the polymer removing step comprises the step of supplying an inorganic polymer removal liquid to the substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an illustrative plan view for explaining the configuration of a substrate treating apparatus according to an embodiment of the present invention;

FIG. 2 is an illustrative transverse sectional view for explaining the configuration of a chemical liquid treatment unit;

FIGS. 3(a) and 3(b) are illustrative sectional views showing an example of the configuration of a two-fluid spray nozzle;

FIG. 4 is an illustrative sectional view showing the configuration of a scrubbing unit;

FIG. 5 is an illustrative view for explaining an example of the configuration of a polymer removal unit;

FIG. 6 is an illustrative sectional view for explaining the configuration of a bevel cleaning unit;

FIG. 7 is an illustrative partially enlarged sectional view for explaining bevel cleaning treatment;

FIG. 8 is a plan view for explaining the arrangement and the operation of a clamp member provided in a spin chuck;

FIG. 9 is an illustrative sectional view for explaining the configuration of a gas phase cleaning unit;

FIG. 10 is an illustrative plan view showing a first specific example of the configuration of the substrate treating apparatus;

FIGS. 11(a), 11(b), and 11(c) are illustrative sectional views showing the steps of a substrate treatment process by the configuration shown in FIG. 10;

FIG. 12 is an illustrative plan view showing a second specific example of the configuration of the substrate treating apparatus;

FIGS. 13(a) to 13(e) are illustrative sectional views showing the steps of a substrate treatment process by the configuration shown in FIG. 12;

FIG. 14 is an illustrative plan view showing a third specific example of the configuration of the substrate treating apparatus;

FIGS. 15(a), 15(b), and 15(c) are illustrative sectional views showing the steps of a substrate treatment process by the configuration shown in FIG. 14;

FIG. 16 is an illustrative plan view showing a fourth specific example of the configuration of the substrate treating apparatus;

FIG. 17 is an illustrative sectional view for explaining treatment in a bevel cleaning unit in the configuration shown in FIG. 16;

FIG. 18 is an illustrative plan view showing a fifth specific example of the configuration of the substrate treating apparatus; and

FIGS. 19(a) to 19(d) are illustrative sectional views showing the steps of a substrate treatment process by the configuration shown in FIG. 18.

### DESCRIPTION OF THE PREFERRED EMBODIMENTS

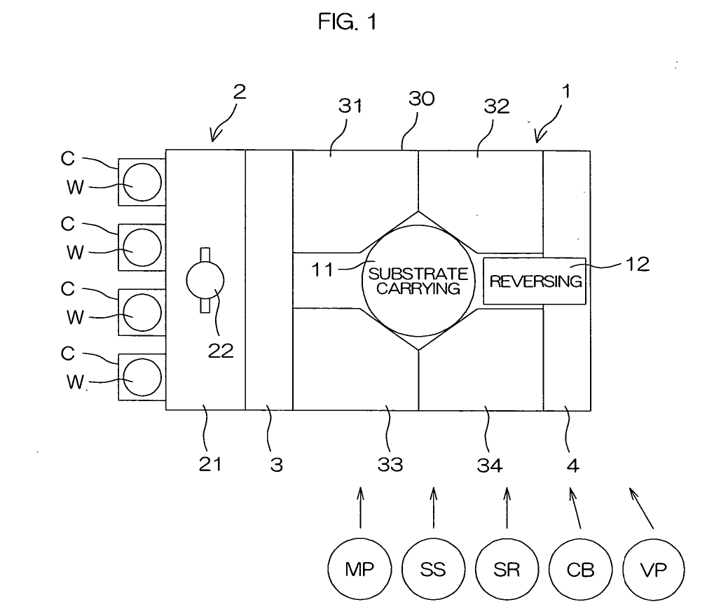

FIG. 1 is an illustrative plan view for explaining the configuration of a substrate treating apparatus according to an embodiment of the present invention. The substrate treating apparatus is a sheeting or single-substrate-processing type apparatus for subjecting a substrate W, which is represented by a semiconductor wafer or a glass substrate for a liquid crystal display device, to treatment using a treatment liquid or a treating gas.

The substrate treating apparatus comprises a substrate treatment section 1 for treating the substrate W, an indexer section 2 coupled to the substrate treatment section 1, and treatment fluid boxes 3 and 4 accommodating a structure for supplying/discharging a treatment fluid (a liquid or a gas).

The indexer section 2 comprises a cassette holder 21 capable of holding a plurality of cassettes C for accommodating the substrate W (FOUP (Front Opening Unified Pod), SMIF (Standard Mechanical Interface) pod, OC (Open Cassette), etc. accommodating a plurality of substrates W in a sealed state), and an indexer robot 22 for accessing the cassette C held in the cassette holder 21 to take out the substrate W, which has not been treated yet, from the cassette C or accommodate the substrate W, which has already been treated, in the cassette C. Each of the cassettes C comprises a plurality of shelves (not shown) for stacking the plurality of substrates W with the substrates slightly spaced in the vertical direction and holding the stacked substrates W. The substrates W can be respectively held in the shelves. Each of the shelves is so constructed as to come into contact with a peripheral edge on a lower surface of the substrate W to hold the substrate W from below. The substrate W is accommodated within the cassette C in such a substantially horizontal posture that its surface directed upward and its reverse surface directed downward.

The substrate treatment section 1 comprises a substrate carrying robot 11 arranged near its center as viewed from the top, and a frame 30 on which the substrate carrying robot 11 is mounted. In the frame 30, a plurality of (four in the present embodiment) unit arrangement sections 31, 32, 33, and 34 are provided so as to surround the substrate carrying robot 11, and a substrate reversing unit 12 is further mounted at a position which can be accessed by the substrate carrying robot 11.

An arbitrary treatment unit selected out of a chemical liquid treatment unit MP, a scrubbing unit SS, a polymer removal unit SR, a bevel cleaning unit CB, and a gas phase cleaning unit VP can be mounted on each of the unit arrangement sections 31, 32, 33, and 34. That is, the frame 30 provides a platform common among the plurality of types (five types in the present embodiment) of treatment units, and is so constructed that a plurality of types (a maximum of four types) of treatment units can be arbitrarily combined and carried thereon. This makes it possible to easily cope with a process corresponding to a new material or a process corresponding to miniaturization. When two types of treatment units are carried on the frame 30, one treatment unit of the first type and three treatment units of the second type can be also carried thereon, or two treatment units of the first type and two treatment units of the second type can be also carried thereon in conformity with a treatment tact.

The substrate carrying robot 11 can receive the substrate W, which has not been treated yet, from the indexer robot 22, and can transfer the substrate W, which has already been treated, to the indexer robot 22. The substrate carrying robot 11 can access the treatment units arranged in the unit arrangement sections 31 to 34 and the substrate reversing unit 12, and can receive and transfer the substrate W from and to the treatment units and the substrate reversing unit 12.

More specifically, the substrate carrying robot 11 comprises, for example, a base fixed to the frame 30 in the substrate treating apparatus, an up-and-down base mounted on the base so as to be movable up and down, a rotating base mounted on the up-and-down base so as to be rotatable around a vertical axis, and a pair of substrate holding hands mounted on the rotating base. The pair of substrate holding hands is constructed so as to be respectively movable back and forth in directions nearer to/away from the axis of rotation of the rotating base. By such a configuration, the substrate carrying robot 11 can direct the substrate holding hands toward any one of the indexer robot 22, the treatment units arranged in the unit arrangement sections 31 to 34, and the substrate reversing unit 12 to move the substrate holding hands back and forth in the state, thereby allowing the substrate W to be delivered.

The pair of substrate holding hands is appropriately used such that one of them is used for holding the substrate W which has not been treated yet and the other one is used for holding the substrate W which has already been treated. The pair of substrate holding hands may be operated so as to receive the substrate W by one of the substrate holding hands from the counterpart substrate holding hand and transfer the substrate W by the other substrate holding hand to the counterpart substrate holding hand in receiving and transferring the substrate W from and to the indexer robot 22, the treatment units arranged in the unit arrangement sections 31 to 34, and the substrate reversing unit 12.

The indexer robot 22 is operated so as to take out the substrate W, which has not been treated yet, from any one of the cassettes C to transfer the substrate W to the substrate carrying robot 11 as well as to receive the substrate W, which has already been treated, from the substrate carrying robot 11 to accommodate the substrate W in the cassette C. The substrate W which has already been treated may be accommodated in the cassette C in which the substrate W has been accommodated in an untreated state. Alternatively, the cassettes C which accommodate the substrate W which has not been treated yet and the cassettes C which accommodate the substrate W which has already been treated may be classified so that the substrate W which has already been treated is accommodated in the cassette C other than the cassette C in which the substrate W has been accommodated in an untreated state.

The substrate carrying robot 11 can carry the substrate W into the substrate reversing unit 12 to reverse the surface and reverse surface of the substrate W. Therefore, in the treatment units arranged in the unit arrangement sections 31 to 34, either one of a device formation surface and a non-device formation surface of the substrate W can be treated.

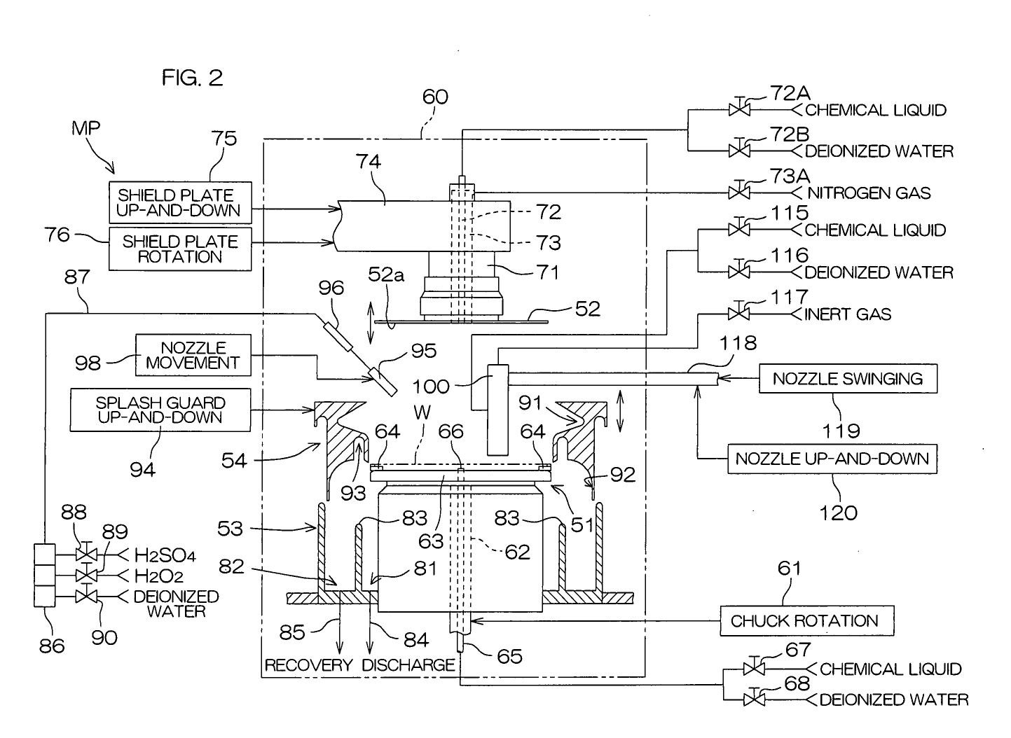

FIG. 2 is an illustrative sectional view for explaining the configuration of the chemical liquid treatment unit MP. The chemical liquid treatment unit MP is a sheeting or single-substrate-processing type treatment unit for subjecting a substrate W in a substantially circular or disk shape such as a semiconductor wafer, for example, to treatment using a treatment liquid, and comprises in a treatment chamber 60 a spin chuck 51 for holding the substrate W in a substantially horizontal posture as well as rotating the substrate W around a substantially vertical axis of rotation passing through its center.

The spin chuck 51 comprises a spin base 63 fixed to an upper end of a rotating shaft 62 rotated by a chuck rotation driving mechanism 61 and having a substantially circular disk shape and a plurality of clamp members 64 spaced at substantially equal angles at a plurality of positions of a peripheral edge of the spin base 63 for clamping the substrate W thereamong. The rotating shaft 62 is a hollow shaft, and a lower surface treatment liquid supply pipe 65, to which a chemical liquid or deionized water serving as a treatment liquid is selectively supplied, is inserted through the rotating shaft 62. The lower surface treatment liquid supply pipe 65 extends to a position in close proximity to the center of a lower surface of the substrate W held in the spin chuck 51, and has a lower surface nozzle 66 for discharging the treatment liquid toward the center of the lower surface of the substrate W at its front end.

To the lower surface treatment liquid supply pipe 65, a chemical liquid (particularly, an etchant) from a chemical liquid supply source can be supplied through a chemical liquid supply valve 67, and deionized water from a deionized water supply source can be supplied through a deionized water supply valve 68.

A shield plate 52 in a circular disk shape having approximately the same diameter as that of the substrate W and having a substrate opposite surface 52 a opposed to an upper surface of the substrate W on its lower surface is provided above the spin chuck 51. A rotating shaft 71 along an axis common to the rotating shaft 62 in the spin chuck 51 is fixed to an upper surface of the shield plate 52. The rotating shaft 71 is a hollow shaft, and a treatment liquid nozzle 72 for supplying a treatment liquid (a chemical liquid from a chemical liquid supply valve 72A or deionized water from a deionized water supply valve 72B) to the upper surface of the substrate W is inserted in the rotating shaft 71. Further, a nitrogen gas supply passage 73 for supplying a nitrogen gas serving as an inert gas toward the center of the upper surface of the substrate W is formed between an inner wall surface of the rotating shaft 71 and an outer wall surface of the treatment liquid nozzle 72. The nitrogen gas supplied from the nitrogen gas supply passage 73 is supplied to a space between the upper surface of the substrate W and the lower surface of the shield plate 52, to form an air current directed toward a peripheral edge of the substrate W. A nitrogen gas from a nitrogen gas supply valve 73A is supplied to the nitrogen gas supply passage 73.

The rotating shaft 71 is mounted in a state where it hangs from the vicinity of a front end of an arm 74 provided along a substantially horizontal direction. In relation to the arm 74, there is provided a shield plate up-and-down driving mechanism 75 for raising and lowering the shield plate 52 between a proximity position where it comes nearer to the upper surface of the substrate W held in the spin chuck 51 and a retreat position where it greatly retreats toward a position above the spin chuck 51 by raising and lowering the arm 74. Further, in relation to the arm 74, there is provided a shield plate rotation driving mechanism 76 for rotating the shield plate 52 in substantial synchronization with the rotation of the substrate W by the spin chuck 51.

The vicinity of the upper surface of the substrate W can be held in a nitrogen gas atmosphere by bringing the substrate opposite surface 52a of the shield plate 52 nearer to the upper surface of the substrate W as well as introducing a nitrogen gas between the substrate opposite surface 52a and the substrate W. By subjecting the substrate W to spin drying treatment in this state, the occurrence of a water mark at the time of drying can be restrained. Particularly in cleaning treatment requiring high-precision cleaning as before a silicide process, the substrate W can be also dried by etching an oxide film using a hydrofluoric acid, and then restraining the occurrence of a water mark while restraining the growth of a natural oxide film, for example. Further, high exchangeability is obtained by rotating the substrate W at high speed, thereby making it possible to keep the loss (film thickness reduction) of a sidewall (a sidewall adhering to a sidewall of a gate) at the time of hydrofluoric acid etching to a minimum.

The spin chuck 51 is accommodated in a treatment cup 53 in the shape of a closed-end container. A discharge groove 81 for discharging a treatment liquid which has been used for treating the substrate W is formed so as to surround the spin chuck 51, and a recovery groove 82 for recovering the treatment liquid (particularly, a chemical liquid) which has been used for treating the substrate W is further formed so as to surround the discharge groove 81. The discharge groove 81 and the recovery groove 82 are partitioned by a cylindrical partition wall 83 formed therebetween. Further, a discharge line 84 for introducing the treatment liquid to a discharge treatment facility (not shown) is connected to the discharge groove 81, and a recovery line 85 for introducing the treatment liquid to a recovery treatment facility (not shown) is connected to the recovery groove 82.

A splash guard 54 for preventing the treatment liquid from the substrate W from being scattered outward is provided above the treatment cup 53. The splash guard 54 has a shape which is substantially symmetrical about an axis of rotation of the substrate W, and an inner surface of its upper part is a discharged liquid acquisition section 91 having a laterally-facing V shape in cross section opened so as to be opposed to the axis of rotation of the substrate W. Further, a recovered liquid acquisition section 92 formed in the shape of a concavely-curved downward-inclined surface directed radially outward in the rotation of the substrate W is formed below the splash guard 54. A partition wall accommodation groove 93 for receiving the partition wall 83 in the treatment cup 53 is formed in the vicinity of an upper end of the recovered liquid acquisition section 92.

In relation to the splash guard 54, there is provided a splash guard up-and-down driving mechanism 94 including a ball screw mechanism or the like, for example. The splash guard up-and-down driving mechanism 94 moves the splash guard 54 up and down between a recovery position (a position shown in FIG. 2) where the recovered liquid acquisition section 92 is opposed to a peripheral end surface of the substrate W held in the spin chuck 51 and a discharge position where the discharged liquid acquisition section 91 is opposed to an end surface of the substrate W held in the spin chuck 51. Further, the splash guard up-and-down driving mechanism 94 makes the splash guard 54 retreat to a retreat position below the discharge position when the substrate W is carried into/out of the spin chuck 51.

The chemical liquid treatment unit MP further comprises a movement nozzle 95 capable of moving a position where a treatment liquid (a chemical liquid or deionized water) is supplied on the substrate W while supplying the treatment liquid to the surface of the substrate W. The movement nozzle 95 is composed of a straight nozzle (normal nozzle) in the present embodiment. In the present embodiment, a resist stripping liquid serving as a chemical liquid (e.g., a high-temperature and high-concentration chemical liquid such as a mixture of a sulfuric acid and a hydrogen peroxide solution) and deionized water serving as a rinsing liquid are selectively supplied to the movement nozzle 95. Consequently, resist stripping treatment can be performed.

Specifically, a treatment liquid from an outlet port of a mixing valve 86 is supplied to the movement nozzle 95 through a treatment liquid supply pipe 87. The mixing valve 86 is provided with three inlet ports. To the inlet ports, a sulfuric acid at high temperature (e.g., a sulfuric acid heated to approximately 80° C.) is supplied through a sulfuric acid valve 88, and a hydrogen peroxide solution (e.g., a hydrogen peroxide solution at room temperature) is supplied through a hydrogen peroxide valve 89, and deionized water is supplied through a deionized water supply valve 90. Further, a throughflow pipe with an agitating fin 96 for agitating the treatment liquid from the mixing valve 86 is set in the treatment liquid supply pipe 87.

By this configuration, the sulfuric acid and the hydrogen peroxide solution are mixed using the mixing valve 86 by opening the sulfuric acid valve 88 and the hydrogen peroxide valve 89 in a state where the deionized water supply valve 90 is closed, and are sufficiently agitated using the throughflow pipe with the agitating fin 96, to produce an SPM (sulfuric acid/hydrogen peroxide mixture) solution containing H₂SO₅ having a strong oxidative force. The SPM solution is discharged to the surface of the substrate W from the movement nozzle 95 as a resist stripping liquid. Further, deionized water can be supplied to the movement nozzle 95 through the treatment liquid supply pipe 87 and the throughflow pipe with the agitating fin 96 from the mixing valve 86 by closing the sulfuric acid valve 88 and the hydrogen peroxide valve 89 and opening the deionized water supply valve 90, and can be discharged toward the surface of the substrate W from the movement nozzle 95. A deionized water nozzle for supplying deionized water to the substrate W may be provided separately from the movement nozzle 95 for supplying the resist stripping liquid.

In resist stripping treatment using a mixture of a sulfuric acid and a hydrogen peroxide solution, the growth and the reduction of an oxide film can be also restrained in a resist stripping process around a gate formed on the substrate W. Further, the stripping of a resist after ion implantation is also allowed, thereby making it possible to reduce damage to the substrate W, as compared with that in a case where the resist is stripped by dry ashing.

The throughflow pipe with the agitating fin 96 is so constructed that a plurality of agitating fins each composed of a rectangular plate-shaped member, which is twisted at an angle of approximately 180 degrees with the direction of liquid flow taken as its axis, are arranged within its pipe member by making an angle around a center axis of the pipe along the direction of liquid flow alternately differing by 90 degrees, examples of which include the one provided under a trade name “MX Series: Inline Mixer” by Noritake Co., Ltd. and ADVANCE ELECTRIC CO., LTD. In the throughflow pipe with the agitating fin 96, the mixture of the sulfuric acid and the hydrogen peroxide solution is sufficiently agitated, so that a chemical reaction (H₂SO₄+H₂O₂→H₂SO₅+H₂O) between the sulfuric acid and the hydrogen peroxide solution occurs, to produce an SPM solution containing H₂SO₅ having a strong oxidative force. In the case, heat (reaction heat) is generated by the chemical reaction. By the heat generation, the liquid temperature of the SPM solution is reliably raised to a high temperature (e.g., not less than 80° C. and more specifically, approximately 120° C.) at which the resist film formed on the surface of the substrate W can be satisfactorily stripped.

A nozzle movement mechanism 98 for moving the movement nozzle 95 is coupled to the movement nozzle 95. While the substrate W is being rotated by the spin chuck 51, the treatment liquid is supplied from the movement nozzle 95 while moving the movement nozzle 95, thereby allowing uniform treatment for the upper surface of the substrate W.

FIG. 2 illustrates an example in which a resist stripping liquid is supplied as a chemical liquid to the movement nozzle 95. A surface treatment liquid such as a fluoric acid for cleaning the surface of the substrate or etching treatment, SC1 (a mixture of ammonia and a hydrogen peroxide solution), or SC2 (a mixture of a hydrochloric acid and a hydrogen peroxide solution) may be supplied as a chemical liquid to the movement nozzle 95.

The chemical liquid treatment unit MP further comprises a two-fluid spray nozzle 100 for supplying a jet of droplets of a treatment liquid to the surface of the substrate W. To the two-fluid spray nozzle 100, the chemical liquid can be supplied through a chemical liquid supply valve 115, deionized water can be supplied through a deionized water supply valve 116, and an inert gas such as a nitrogen gas can be supplied through an inert gas supply valve 117. Further, the two-fluid spray nozzle 100 is coupled to a swinging arm 118. The swinging arm 118 is swung along the upper surface of the substrate W by a nozzle swinging mechanism 119, and is raised or lowered by a nozzle up-and-down mechanism 120. Thus, the two-fluid spray nozzle 100 swings on the substrate W, and is moved by drawing an arc leading to a peripheral edge of the substrate W from the center of the radius in the rotation of the substrate W, for example.

A polymer removal liquid, for example, can be supplied as a chemical liquid to the two-fluid spray nozzle 100. Consequently, treatment for removing a resist residue (a polymer) remaining on the surface of the substrate W after resist stripping treatment can be satisfactorily performed by the chemical action of the polymer removal liquid and the physical action due to collisions of a jet of droplets. Further, fine particles can be together removed. Only the deionized water, for example, may be supplied to the two-fluid spray nozzle 100, thereby making it possible to satisfactorily remove particles adhering to the surface of the substrate W by the physical action due to collisions of a jet of droplets of the deionized water.

It is preferable that a pre-dispensing function is carried on each of the nozzles. This allows the chemical liquid to be discharged at a stable temperature.

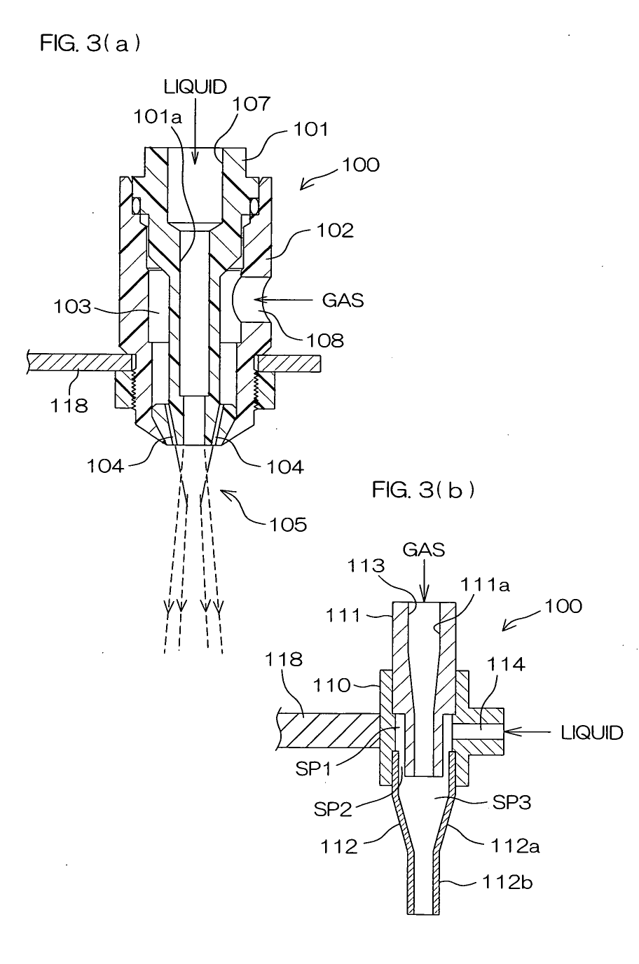

FIGS. 3(a) and 3(b) are illustrative sectional views showing an example of the configuration of the two-fluid spray nozzle 100. FIG. 3(a) illustrates the configuration of a so-called external mixing type two-fluid spray nozzle, and FIG. 3(b) illustrates the configuration of a so-called internal mixing type two-fluid spray nozzle.

In the external mixing type two-fluid spray nozzle shown in FIG. 3(a), a liquid inlet section 101 and a gas inlet section 102 having a larger diameter than that of the liquid inlet section 101 are coaxially fitted to each other, to constitute its casing.

The liquid inlet section 101 almost penetrates the gas inlet section 102, a liquid supply passage 101 a formed inside thereof communicates with an outer space in the vicinity of a front end of the two-fluid spray nozzle, and its inlet forms a liquid inlet port 107.

On the other hand, the gas inlet section 102 has a gas inlet port 108 on its side surface, and the gas inlet port 108 communicates with a space 103 formed between its inner wall and an outer wall of the liquid inlet section 101 inside the gas inlet section 102. A front end of the liquid inlet section 101 is formed in a collar shape expanding outward, and a gas passage 104 for communicating the space 103 and the outside space in the vicinity of the front end of the two-fluid spray nozzle is formed in the collar-shaped end.

By this configuration, when a liquid is supplied to the liquid supply passage 101a and a gas is supplied from a gas inlet 102a, the liquid and the gas are mixed in air outside the casing in an outer space 105 in the vicinity of the front end of the two-fluid spray nozzle, thereby forming droplets. The droplets are sprayed along the direction in which the liquid and the gas are blown off, that is, the axial direction of the liquid inlet section 101. It is preferable that the gas introduced into the gas inlet 108 is an inert gas such as dry air or a nitrogen gas.

On the other hand, the internal mixing type two-fluid spray nozzle shown in FIG. 3(b) has a casing which connects a gas inlet section 111, a liquid inlet section 110, and a droplet formation and discharge section 112, and is constructed by connecting them. The gas inlet section 111, the liquid inlet section 110, and the droplet formation and discharge section 112 respectively have tubular shapes, and are connected in series to constitute a two-fluid spray nozzle 100.

The droplet formation and discharge section 112 is connected to a lower end of the liquid inlet section 110, and has a tapered part 112a whose inner diameter decreases downward and a straight part 112b connecting with a lower end of the tapered part 112a and having the shape of a straight pipe whose inner diameter is uniform.

The gas inlet section 111 has a large diameter portion engaged with the upper side of the liquid inlet section 110 and a small diameter portion connecting with a lower part of the large diameter portion to reach an inner space of the tapered part 112a in the droplet formation and discharge section 112. A gas inlet passage 111a in a tapered shape is formed inside the gas inlet section 111, and its inlet forms a gas inlet port 113.

A liquid inlet port 114 for introducing a liquid is formed so as to be opened sideward in the liquid inlet section 110. The liquid inlet port 114 communicates with a ring-shaped space SP1 between the small diameter portion of the gas inlet section 111 and the inner wall of the liquid inlet section 110. The space SP1 communicates with an inner space SP3 (a mixing chamber) of the tapered part 112a of the droplet formation and discharge section 112 through a ring-shaped space SP2 between the small diameter portion of the gas inlet section 111 and the inner wall of the droplet formation and discharge section 112.

In the internal mixing type two-fluid spray nozzle 100, a gas supplied from the gas inlet port 113 and a liquid supplied through the spaces SP1 and SP2 from the liquid inlet port 114 are mixed in the space SP3. As a result, droplets are formed. The droplets are accelerated by the tapered part 112a, and are sprayed toward the substrate W through the straight part 112b. A jet of the droplets has significantly good straight properties by the function of the straight part 112b.

Comparison is made between the external mixing type two-fluid spray nozzle and the internal mixing type two-fluid spray nozzle. The external mixing type two-fluid spray nozzle has the disadvantage that the straight properties of the droplets are not better, as compared with the internal mixing type two-fluid spray nozzle, so that the jet of droplets expand in an umbrella shape. On the other hand, the external mixing type two-fluid spray nozzle has the advantage that the pressure of the gas is not returned toward the liquid because the mixture of the liquid and the gas does not exist inside thereof, so that the flow rate of the liquid is hardly changed even if the flow rate of the gas is changed.

The movement nozzle 95 may be composed of a two-fluid spray nozzle. Alternatively, the two-fluid spray nozzle 100 may be replaced with a straight nozzle.

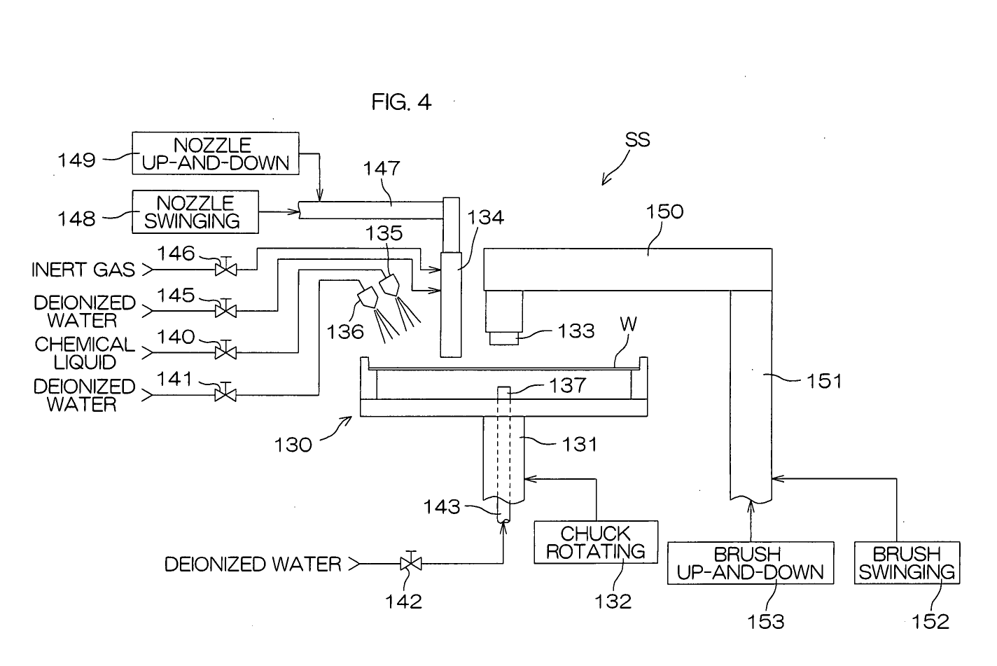

FIG. 4 is an illustrative sectional view showing the configuration of a scrubbing unit SS. The scrubbing unit SS is a sheeting or single-substrate-processing type treatment unit comprising a spin chuck 130 which is rotated with-a substrate W held almost horizontally, a chuck rotating mechanism 132 for applying a rotating force to a rotating shaft 131 in the spin chuck 130, a scrub brush 133 for scrubbing an upper surface of the substrate W held in the spin chuck 130, and a two-fluid spray nozzle 134 for supplying a jet of droplets of a treatment liquid to the upper surface of the substrate W held in the spin chuck 130. Further, the scrubbing unit SS comprises a chemical liquid nozzle 135 for supplying a chemical liquid (e.g., a thin etchant) to the upper surface of the substrate W held in the spin chuck 130, an upper surface deionized water nozzle 136 for similarly supplying deionized water to the upper surface of the substrate W, and a lower surface deionized water nozzle 137 for supplying deionized water to a lower surface of the substrate W held in the spin chuck 130.

The chemical liquid is supplied to the chemical liquid nozzle 135 through a chemical liquid supply valve 140, the deionized water is supplied to the upper surface deionized water nozzle 136 through a deionized water supply valve 141, and the deionized water is supplied to the lower surface deionized water nozzle 137 through a treatment liquid supply pipe 143 inserted through the hollow rotating shaft 131 from a deionized water supply valve 142. The lower surface deionized water nozzle 137 is coupled to an upper end of the treatment liquid supply pipe 143, to discharge the deionized water toward the rotation center of the lower surface of the substrate W held in the spin chuck 130. The deionized water expands radially outward in the rotation through the lower surface of the substrate W upon receipt of a centrifugal force, to lead to the whole area of the lower surface of the substrate W.

Furthermore, to the two-fluid spray nozzle 134, deionized water is supplied from a deionized water supply valve 145, and an inert gas (a nitrogen gas, etc.) is supplied from an inert gas supply valve 146. The two-fluid spray nozzle 134 is coupled to a swinging arm 147 which swings along the substrate W. A nozzle swinging mechanism 148 and a nozzle up-and-down mechanism 149 are coupled to the swinging arm 147. The swinging arm 147 is swung by the functions, so that the two-fluid spray nozzle 134 is swung in a range leading to the peripheral edge from the rotation center of the substrate W held in the spin chuck 130. Further, the swinging arm 147 is raised and lowered so that the two-fluid spray nozzle 134 is displaced nearer to/away from the substrate W.

By rotating the spin chuck 130 as well as moving the two-fluid spray nozzle 134 toward the peripheral edge from the rotation center of the substrate W while discharging the jet of droplets of the treatment liquid from the two-fluid spray nozzle 134, the whole surface of the substrate W can be subjected to cleaning treatment using the jet of droplets. In the cleaning treatment by the two-fluid spray nozzle 134, particles can be removed without damaging a fine pattern on the substrate W, thereby restraining problems such as the destruction of a gate pattern on the substrate W.

It is preferable that the nozzle swinging mechanism 148 is controlled so as to variably control the speed of movement of the two-fluid spray nozzle 134. Consequently, the speed of movement of the two-fluid spray nozzle 134 can be changed in the vicinity of the rotation center of the substrate W and in the vicinity of the peripheral edge thereof, thereby allowing each of portions of the substrate W to be uniformly cleaned.

On the other hand, the scrub brush 133 is held in one end of a swinging arm 150 with the scrub brush directed downward so as to be opposed to the substrate W held in the spin chuck 130. The other end of the swinging arm 150 is coupled to a rotating shaft 151 along a vertical direction parallel to the rotating shaft 130. A brush swinging mechanism 152 and a brush up-and-down mechanism 153 are coupled to the rotating shaft 151. By the functions, the swinging arm 150 is swung along the substrate W so that the scrub brush 133 is moved back and forth between the rotation center and the peripheral edge of the substrate W, and the swinging arm 150 is moved up and down so that the scrub brush 133 is moved nearer to and away from the upper surface of the substrate W. The spin chuck 130 is rotated while the scrub brush 133 is brought into contact with the upper surface of the substrate W and is moved toward the peripheral edge from the rotation center of the substrate W, thereby performing brush cleaning treatment for the whole surface of the substrate W. At this time, the supply of the chemical liquid from the chemical liquid nozzle 135 and the supply of the deionized water from the upper surface deionized water nozzle 136 are concurrently performed. Usable as the scrub brush 133 is one made of a material such as polyvinylchloride, mohair, nylon, or polypropylene.

It is preferable that the brush swinging mechanism 152 is controlled such that the speed of movement of the scrub brush 133 is variably controlled, similarly to the two-fluid spray nozzle 134. Consequently, the speed of movement of the scrub brush 133 can be changed in the vicinity of the rotation center of the substrate W and the vicinity of the peripheral edge thereof, thereby allowing each of portions of the substrate W to be uniformly cleaned.

In a case where the upper surface of the substrate W is subjected to physical cleaning treatment by the two-fluid spray nozzle 134 or the scrub brush 133, if deionized water is supplied to the lower surface of the substrate W from the lower surface deionized water nozzle 137, cover rinsing treatment for protecting the lower surface of the substrate W by a liquid film of deionized water can be performed. Consequently, a contaminant can be prevented from detouring toward the lower surface of the substrate W from the upper surface thereof to adhere to the substrate W again.

The scrubbing unit SS may comprise a nozzle having a cleaning effect by another physical action such as a ultrasonic nozzle for supplying to the substrate W a treatment liquid given ultrasonic vibration (e.g., vibration having a frequency of 1.5 MHz) or a high-pressure jet nozzle for spraying a treatment liquid toward the substrate W at high pressure in place of the two-fluid spray nozzle 134 or in addition to the two-fluid spray nozzle 134.

It is preferable that a mechanism for all cleaning applications such as brush cleaning, ultrasonic cleaning, high-pressure jet cleaning, and two fluid spray cleaning, for example, can be carried on one head (a swinging arm). It is preferable that two or more types of scrub brushes (e.g., ones made of different materials) can be carried on one head. These configurations make it possible to cope with a wider cleaning process.

FIG. 5 is an illustrative view for explaining an example of the configuration of the polymer removal unit SR. The polymer removal unit SR is a sheeting or single-substrate-processing type treatment unit for removing a polymer (a resist residue) adhering to a substrate W after the resist stripping treatment by the above-mentioned chemical liquid treatment unit MP and resist stripping treatment by ashing. More specifically, in the step of pattern-forming copper wiring, tungsten wiring, or polysilicon wiring, for example, etching treatment is performed for selectively removing a copper wiring film, a tungsten wiring film, or a polysilicon wiring film which are uniformly formed on the substrate W, and then resist stripping treatment is performed for removing a resist pattern used for the etching treatment. In such a case, the polymer removal unit SR is used to remove a resist residue which remains as a polymer without being removed by the resist stripping treatment.

The polymer removal unit SR comprises a spin chuck 160 for horizontally holding and rotating the substrate W in a treatment chamber 155, and further comprises a chemical liquid nozzle 161 for supplying a chemical liquid for removing a polymer to an upper surface of the substrate W held in the spin chuck 160 and a deionized water nozzle 162 for supplying deionized water to the upper surface of the substrate W held in the spin chuck 160. Examples of the chemical liquid for polymer removal is as described above.

Used as the spin chuck 160 is one of a vacuum suction type (a vacuum chuck) capable of horizontally holding the substrate W by vacuum sucking a non-device formation surface (lower surface) of the substrate W in a state where a device formation surface of the substrate W is directed upward, for example. The spin chuck 160 of a vacuum suction type can rotate the held substrate W within a horizontal surface by rotating the substrate W around a vertical axis with the substrate W held therein, for example.

The spin chuck 160 is accommodated within a treatment cup 163. The treatment cup 163 surrounds the spin chuck 160, and has an annular discharge groove 164 for discharging deionized water or the like which has been used for treating the substrate W and an annular recovery groove 165 for recovering a chemical liquid which has been used for treating the substrate W at the bottom. The discharge groove 164 and the recovery groove 165 are partitioned by a cylindrical partition wall 166, and an exhaust passage 167 having its one end facing the discharge groove 164 and opened is formed below the partition wall 166. An in-cup exhaust pipe 168 extending toward an exhaust facility is connected to the other end of the exhaust passage 167.

In relation to the treatment cup 163, there is provided a splash guard 170 for acquiring a chemical liquid or deionized water to be scattered from the substrate W. The splash guard 170 has a shape which is substantially symmetrical about an axis of rotation of the substrate W, and an inner surface of its upper part is a discharged liquid acquisition section 171, which is in a lateral-V-shape in cross section, opened so as to be opposed to the axis of rotation of the substrate W. Further, a recovered liquid acquisition section 172 having a downward-inclined curved surface directed radially outward in the rotation of the substrate W is formed below the splash guard 170. A partition wall accommodation groove 173 for receiving the partition wall 166 in the treatment cup 163 is formed in the vicinity of an upper end of the recovered liquid acquisition section 172.

The splash guard 170 is constructed so as to be raised and lowered to and from the treatment cup 163, and can oppose the discharged liquid acquisition section 171 or the recovered liquid acquisition section 172 to a peripheral end surface of the substrate W held in the spin chuck 160 or can retreat downward from the position where the substrate W is held by the spin chuck 160 so as not to prevent the substrate W from being carried into or out of the spin chuck 160. In a state where the discharged liquid acquisition section 171 is opposed to the peripheral end surface of the substrate W, the chemical liquid or the deionized water scattered from the substrate W can be acquired in the discharged liquid acquisition section 171. The chemical liquid or the deionized water acquired in the discharged liquid acquisition section 171 flows down through the discharged liquid acquisition section 171, to be collected in the discharge groove 164 in the treatment cup 163 and discharged toward a discharged liquid treatment facility (not shown) from the discharge groove 164. In a state where the recovered liquid acquisition section 172 is opposed to the peripheral end surface of the substrate W, the treatment liquid (mainly, the chemical liquid) scattered from the substrate W can be acquired in the discharged liquid acquisition section 172. The treatment liquid acquired in the recovered liquid acquisition section 172 flows down through the recovered liquid acquisition section 172, to be collected in the recovery groove 165 in the treatment cup 163 and recovered in a recovered liquid treatment facility (not shown) from the recovery groove 165.

A chemical liquid supply pipe 175 for supplying a chemical liquid from a chemical liquid supply source is connected to the chemical liquid nozzle 161. A temperature adjuster 176 for adjusting the chemical liquid to a temperature suitable for treatment and a chemical liquid supply valve 177 for controlling the discharge of the chemical liquid from the chemical liquid nozzle 161 are interposed in this order from the chemical liquid supply source halfway in the chemical liquid supply pipe 175.

A deionized water supply pipe 178 for supplying deionized water from a deionized water supply source is connected to the deionized water nozzle 162. A deionized water supply valve 179 is interposed halfway in the deionized water supply pipe 178. By opening or closing the deionized water supply valve 179, it is possible to supply deionized water to the substrate W from the deionized water nozzle 162 or stop the supply of the deionized water to the substrate W.

The polymer removal unit SR further comprises a two-fluid spray nozzle 180 for supplying a jet of droplets of a treatment liquid to the upper surface of the substrate W held in the spin chuck 160. To the two-fluid spray nozzle 180, a treatment liquid from a treatment liquid supply pipe 181 is supplied, and an inert gas (a nitrogen gas, etc.) is supplied from an inert gas supply valve 182. A chemical liquid (e.g., a polymer removal liquid) from a chemical liquid supply valve 186 or deionized water from a deionized water supply valve 187 can be selectively supplied to the treatment liquid supply pipe 181. Further, the two-fluid spray nozzle 180 is coupled to one end of a swinging arm 183 which swings along the upper surface of the substrate W held in the spin chuck 160. A nozzle swinging mechanism 184 for moving the two-fluid spray nozzle 180 on the substrate W by swinging the swinging arm 183 and a nozzle up-and-down mechanism 185 for moving the two-fluid spray nozzle 180 nearer to/away from the upper surface of the substrate W held in the spin chuck 160 by raising and lowering the swinging arm 183 are coupled to the swinging arm 183.

By such a configuration, even when the residue cannot be completely removed by the chemical liquid because it firmly adheres to the substrate W, the residue can be removed from the substrate W by a physical force due to a jet of droplets discharged from the two-fluid spray nozzle 180. Further, when a chemical liquid (a polymer removal liquid, etc.) serving as a treatment liquid is supplied to the two-fluid spray nozzle 180, the jet of droplets of the chemical liquid is supplied to the substrate W, thereby allowing a residue (a polymer, etc.) to be more efficiently removed by a multiplier effect of the chemical action of the chemical liquid and the physical action of the jet of droplets.

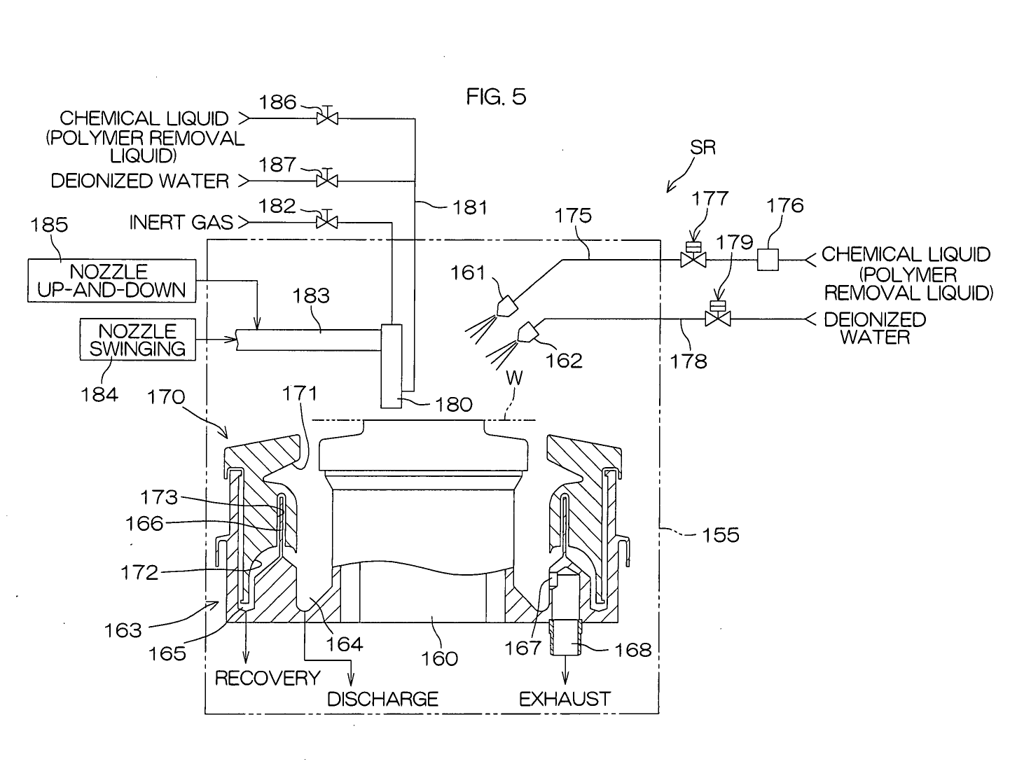

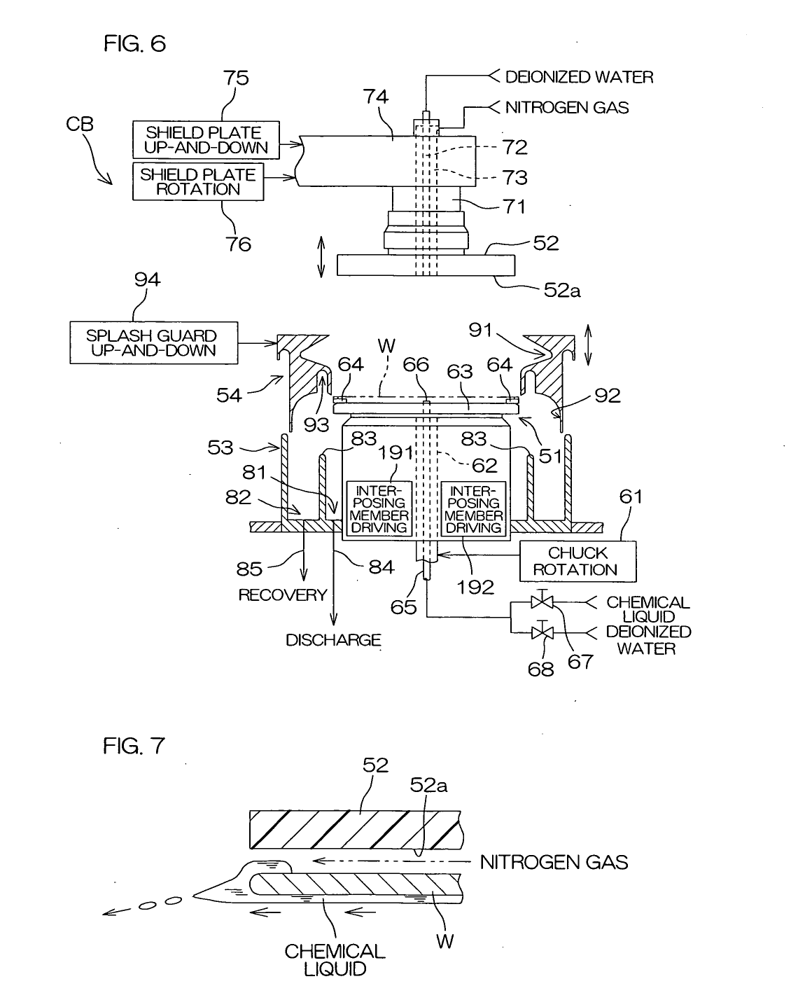

FIG. 6 is an illustrative sectional view for explaining the configuration of the bevel cleaning unit CB. The bevel cleaning unit CB in this example is a sheeting treatment unit, and has a large number of constituent elements similar to the constituent elements composing the chemical liquid treatment unit MP. In FIG. 6, sections having the same functions as those of the sections shown in FIG. 2 are assigned the same reference numerals as those shown in FIG. 2 and hence, the description thereof is not repeated.

The bevel cleaning unit CB in this example neither has a movement nozzle 95 and a structure relating thereto nor a two-fluid spray nozzle 100 and a structure related thereto. In the chemical liquid treatment unit MP, a chemical liquid or deionized water is supplied to a treatment liquid nozzle 72 for supplying a treatment liquid to an upper surface of a substrate W. In the bevel cleaning unit CB in this example, however, the deionized water is exclusively supplied to the treatment liquid nozzle 72.

When the substrate W is held in a spin chuck 51, treatment is started in a state where a shield plate 52 is lowered to a proximity position (e.g., a position where spacing between a substrate opposite surface 52a and an upper surface of the substrate W is 0.3 mm) where it comes nearer to the upper surface of the substrate W held in the spin chuck 51 and is held therein. That is, the spin chuck 51 is rotated at a predetermined rotational speed, so that the substrate W is rotated around a vertical axis passing through its center.

On the other hand, the shield plate 52 is rotated at approximately the same speed in the same direction as the substrate W in a state where it comes nearer to the upper surface of the substrate W. In this state, a chemical liquid supply valve 67 is opened, so that a chemical liquid is discharged from a lower surface nozzle 66 toward the center of a lower surface of the substrate W which is rotated together with the spin chuck 51. The chemical liquid reaches the vicinity of the center of the lower surface of the substrate W, and is introduced into a peripheral edge of the substrate W through the lower surface of the substrate W upon receipt of a centrifugal force caused by the rotation of the substrate W. Consequently, the chemical liquid spreads throughout the whole area of the lower surface of the substrate W, so that the lower surface of the substrate W can be satisfactorily subjected to treatment using the chemical liquid.

The chemical liquid detours toward the upper surface of the substrate W through the peripheral edge of the substrate W, as illustrated in enlarged fashion in FIG. 7. The chemical liquid which has detoured is discharged outward from the substrate W by a centrifugal force after treating the peripheral end surface of the substrate W and a peripheral edge (a bevel portion) of the upper surface thereof. The treatment width at the peripheral edge of the upper surface of the substrate W can be controlled by the rotational speed of the spin chuck 51, the flow rate of a nitrogen gas blown off from the center of the shield plate 52, and the flow rate of the chemical liquid discharged from the lower surface nozzle 66. Consequently, the chemical liquid can be prevented from reaching a central area which is an area inside the peripheral edge on the reverse surface of the substrate W and can restrict treatment in the central area. Since the upper surface of the substrate W is covered with the shield plate 52, the reverse surface and the peripheral end surface of the substrate W can be subjected to selective etching treatment with high precision while protecting a device formation surface (upper surface) from the rebound of the chemical liquid.

When the whole area of the surface, the peripheral end surface, and the peripheral edge on the reverse surface of the substrate W are thus treated by the chemical liquid, the splash guard 54 is raised to a recovery position shown in FIG. 6. Consequently, the chemical liquid discharged outward from the substrate W is acquired in the recovered liquid acquisition section 92 in the splash guard 54, and falls down toward the recovery groove 82 in the treatment cup 53 from a lower edge of the recovered liquid acquisition section 92 through the recovered liquid acquisition section 92. The chemical liquid thus collected in the recovery groove 82 is recovered through the recovery line 85, and is reused for the subsequent chemical liquid treatment.

After the substrate W is subjected to chemical liquid treatment over a predetermined time period in such a manner, the chemical liquid supply valve 67 is closed, so that the discharge of the chemical liquid from the lower surface nozzle 66 is stopped. The splash guard 54 is lowered from the recovery position to a discharge position where the discharged liquid acquisition section 91 in the splash guard 54 is opposed to an end surface of the substrate W held in the spin chuck 51. On the other hand, the deionized water is supplied to the upper surface of the substrate W from the treatment liquid nozzle 72, and the deionized water supply valve 68 is opened so that the deionized water is supplied toward the center of the lower surface of the substrate W from the lower surface nozzle 66. The rotation of the spin chuck 51 is continued. Consequently, the deionized water supplied to the upper and lower surfaces of the substrate W expands throughout the upper and lower surfaces of the substrate W upon receipt of the centrifugal force. Consequently, rinsing treatment for washing away the chemical liquid adhering to the upper and lower surfaces of the substrate W is performed.

The deionized water, which has been subjected to the rinsing treatment, shaken down from the peripheral edge of the substrate W and scattered sideward is acquired in the discharged liquid acquisition section 91 in the splash guard 54 to lead to its lower edge through the discharged liquid acquisition section 91, and falls down toward a discharge groove 81 in the treatment cup 53, to be discharged through a discharge line 84.

When the rinsing treatment is thus terminated, the discharge of the deionized water from the treatment liquid nozzle 72 is stopped. Further, the deionized water supply valve 68 is closed, so that the discharge of the deionized water from the lower surface nozzle 66 is stopped. The spin chuck 51 is rotated at high speed, to perform drying treatment for shaking down droplets adhering to the upper and lower surfaces of the substrate W by the centrifugal force to dry the substrate W. When the drying treatment is terminated, the shield plate 52 is raised to an upper retreat position, and the rotation of the spin chuck 51 is stopped. The splash guard 54 is lowered to the retreat position. In this case, the substrate W, which has been treated, held in the spin chuck 51 is carried out by the substrate carrying robot 11.

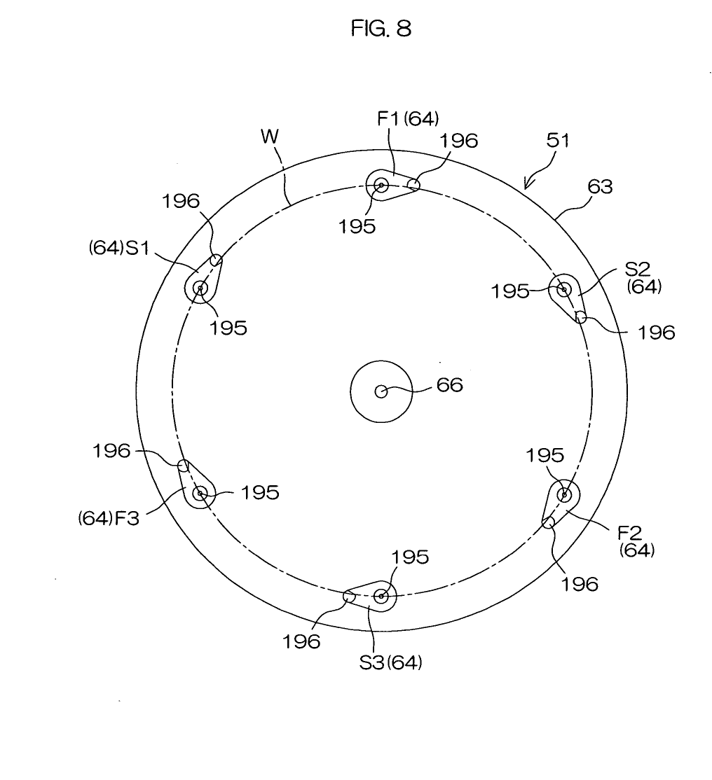

FIG. 8 is a plan view for explaining the arrangement and the operation of clamp members 64 provided in the spin chuck 51. In the spin chuck 51, six clamp members F1 to F3 and S1 to S3 (the clamp member 64) are almost equally spaced at-a peripheral edge of the spin base 63 in a disk shape. Each of the clamp members F1 to F3 and S1 to S3 has a support 195 for point-contacting and supporting a lower surface at a peripheral edge of a substrate W and an clamp portion 196 for clamping a peripheral end surface of the substrate W, and is so constructed as to rotate around a vertical axis with the support 195 taken as its center. Consequently, the interposing portion 196 can take a clamping state where it is abutted against the peripheral end surface of the substrate W and a released state where it is caused to retreat from the peripheral end surface of the substrate W.

A first group of clamp members comprising three alternate clamp members F1 to F3 is synchronously driven by a first clamp member driving mechanism 191 (see FIG. 6), and a second group of clamp members comprising the remaining three alternate clamp members S1 to S3 is synchronously driven by a second clamp member driving mechanism 192 (see FIG. 6).

The first and second clamp member driving mechanisms 191 and 192 are so constructed that even if the spin chuck 51 is being rotated, the clamp members F1 to F3 and S1 to S3 are driven to be opened or closed. During the treatment of the substrate W, therefore, the clamp member driving mechanisms are so controlled as to allow switching from a first clamping state where the peripheral end surface of the substrate W is clamped by the first group of clamp members F1 to F3 to a second clamping state where the peripheral end surface of the substrate W is clamped by the second group of clamp members S1 to S3 through an intermediate clamping state where the peripheral end surface of the substrate W is clamped by both the first and second groups of clamp members F1 to F3 and S1 to S3. When the clamp members enter the second clamping state, they are switched from the first clamping state through the intermediate clamping state. Such operations are repeatedly performed during the treatment of the substrate W so that the position where the substrate W is clamped on the peripheral end surface of the substrate W can be changed. Therefore, the treatment liquid can spread throughout the whole area of the peripheral end surface of the substrate W to perform good treatment over the whole periphery.

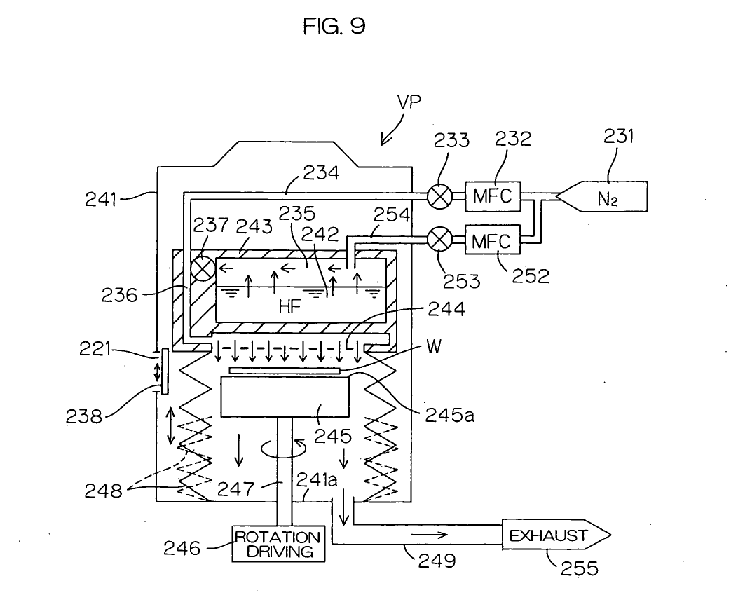

FIG. 9 is an illustrative sectional view for explaining the configuration of the gas phase cleaning unit VP. The gas phase cleaning unit VP is a sheeting treatment unit, and is used for the purpose of drying a hydrofluoric acid process, etching a silicon oxide film at a high selection ratio, and preventing organic matter, inorganic matter, and particles from adhering to a surface of activated silicon.

The gas phase cleaning unit VP comprises a hydrofluoric acid vapor generation chamber 243 storing a hydrofluoric acid solution 242 which is an example of a solution containing an acid in a sealed state within a housing 241. A punching plate 244 formed with a large number of through holes for releasing a vapor including a hydrofluoric acid (a hydrofluoric acid vapor) downward is provided below the hydrofluoric acid vapor generation chamber 243.

A hot plate 245 for holding a substrate W to be treated horizontally with the substrate W opposed to the punching plate 244 is arranged below the punching plate 244. The hot plate 245 is fixed to an upper end of a rotating shaft 247 rotated around a vertical axis by a rotation driving mechanism 246 including a motor or the like.

Bellows 248 which contract up and down with respect to a bottom surface 241a of the housing 241 are provided outside, as viewed from the top, of the hot plate 245. The bellows 248 are driven to extend/contract by a driving mechanism (not shown) between a sealed position where their upper edges are abutted against the periphery of the punching plate 244 to seal a space at a peripheral edge of the hot plate 245 to form a treatment chamber (a position indicated by a solid line in FIG. 9) and a retreat position where the upper edges retreat below an upper surface 245a of the hot plate 245 (a position indicated by a broken line in FIG. 9). The bellows 248 and the housing 241 thus form a treatment chamber having a double structure, so that safety is enhanced. In order to further enhance safety, it is preferable that a gas sensing system is employed to prepare for leakage of the hydrofluoric acid vapor.

An inner space of the bellows 248 is evacuated by an exhaust section 255 through an exhaust pipe 249 connected to the bottom surface 241a of the housing 241. The exhaust section 255 may be a forced exhaust mechanism such as an exhaust blower or an ejector, or may be an exhaust facility provided in a clean room where the substrate surface treating apparatus is installed.

A carrying-in/carrying-out aperture 221 for carrying in/carrying out the substrate W is formed on a sidewall of the housing 241 beside the hot plate 245. A shutter 238 is arranged in the carry-in/out aperture 221. At the time of carrying in/carrying out the substrate W, the bellows 248 are lowered to the retreat position (the position indicated by the broken line in FIG. 9), and the shutter 238 is opened, so that the substrate W is delivered between the substrate carrying robot 11 (see FIG. 1) and the hot plate 245.

A nitrogen gas supply pipe 254 for supplying a nitrogen gas serving as a carrier gas to a space 235 above a liquid surface of the hydrofluoric acid solution 242 is connected to the hydrofluoric acid vapor generation chamber 243. Further, the space 235 can be connected to a hydrofluoric acid vapor supply passage 236 for introducing the hydrofluoric acid vapor to the punching plate 244 through a valve 237. A nitrogen gas from a nitrogen gas supply source 231 is supplied to the hydrofluoric acid vapor supply passage 236 through a flow rate controller (MFC) 232, a valve 233, and a nitrogen gas supply pipe 234.

Furthermore, the nitrogen gas from the nitrogen gas supply source 231 is supplied to a nitrogen gas supply pipe 254 through a flow rate controller 252 and a valve 253. The flow rate of the hydrofluoric acid vapor can be controlled at the flow rate of the nitrogen gas (inert gas) supplied to the nitrogen gas supply pipe 254. Consequently, it is possible to realize treatment which makes it easy to manage the concentration of the hydrofluoric acid vapor supplied to the substrate W, is stable, and is superior in reproducibility.

The hydrofluoric acid solution 242 stored in the hydrofluoric acid vapor generation chamber 243 is prepared to the concentration of a so-called pseudo azeotropic composition (e.g., approximately 39.6% under atmospheric pressure and room temperature (20° C.)). In the hydrofluoric acid solution 242 having the pseudo azeotropic composition, water and hydrogen fluoride are equal in evaporation rate. Even if the hydrofluoric acid vapor is introduced into the punching plate 244 from the valve 237 through the hydrofluoric acid vapor supply passage 236 so that the hydrofluoric acid solution 242 in the hydrofluoric acid vapor generation chamber 243 is reduced, therefore, the concentration of the hydrofluoric acid vapor introduced into the hydrofluoric acid vapor supply passage 236 is kept unchanged.

When a gas phase etching process for removing an unnecessary material on the surface of the substrate W is carried out, the bellows 248 are raised to an adhesion position (the position indicated by the solid line in FIG. 9) where they adhere to a peripheral edge of the punching plate 244, and the valves 233, 253, and 237 are opened. Consequently, the hydrofluoric acid vapor generated in the space 235 within the hydrofluoric acid vapor generation chamber 243 is pushed out toward the hydrofluoric acid vapor supply passage 236 through the valve 237 by the nitrogen gas from the nitrogen gas supply pipe 254. The hydrofluoric acid vapor is further conveyed to the punching plate 244 by the nitrogen gas from the nitrogen gas supply pipe 234. The hydrofluoric acid vapor is supplied to the surface of the substrate W through a through hole formed in the punching plate 244.

On the surface of the substrate W, etching reaction occurs under involvement of water molecules in the vicinity of the substrate W, so that the unnecessary material is separated from the substrate W.

The etching rate by the hydrofluoric acid vapor greatly depends on the temperature of the substrate W. A current is carried into a heater inside the hot plate 245 so as to hold the substrate at a predetermined temperature.

In order to uniformly perform treatment within the surface of the substrate W, the hot plate 245 is rotated around a vertical axis at a predetermined speed by the rotation driving mechanism 246 through the rotating shaft 247.

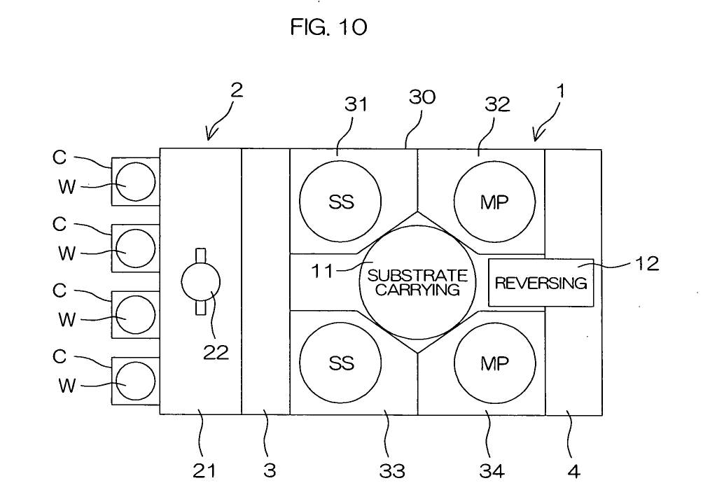

FIG. 10 is an illustrative plan view showing a first specific example of the configuration of the substrate treating apparatus. In the example of the configuration, two chemical liquid treatment units MP and two scrubbing units SS are respectively arranged in unit arrangement sections 31 to 34. That is, the two types of treatment units are mounted on a frame 30 and contained therein. More specifically, the two scrubbing units SS are respectively arranged in the unit arrangement sections 31 and 33 on the side of an indexer section 2, and the two chemical liquid treatment units MP are respectively arranged in the unit arrangement sections 32 and 34 farther from the indexer section 2. Further, a substrate reversing unit 12 for reversing the surface and the reverse surface of the substrate W carried from the treatment unit (here, the chemical liquid treatment units 32 and 34) by a substrate carrying robot 11 is arranged at a position nearer to a treatment fluid box 4 between the two chemical liquid treatment units MP in the unit arrangement sections 32 and 34.

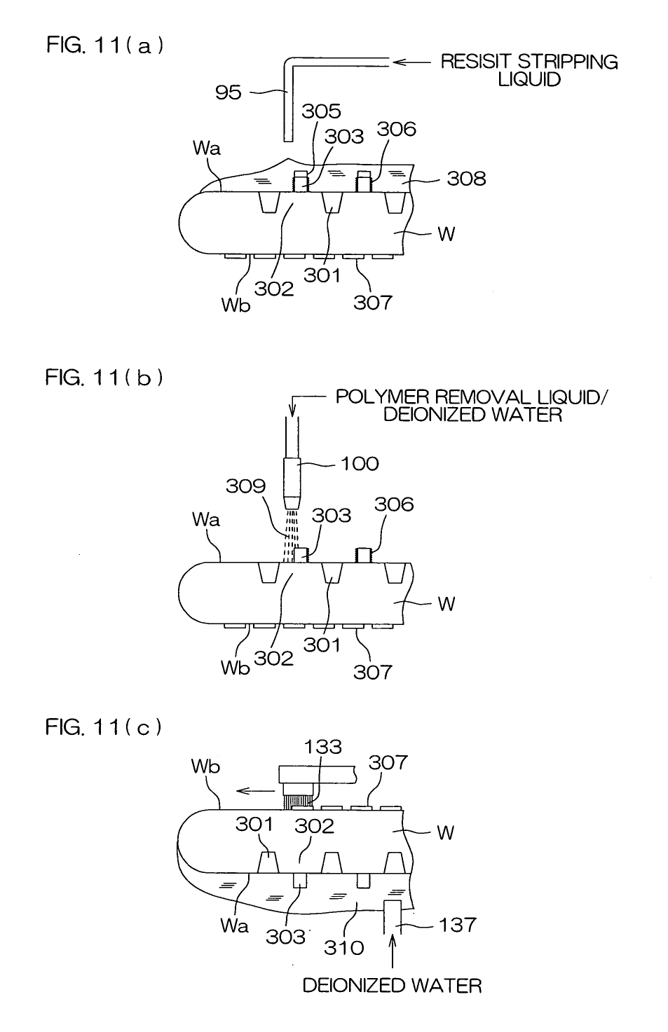

FIGS. 11(a), 11(b), and 11(c) are illustrative sectional views showing the steps of a substrate treatment process by the substrate treating apparatus in the first specific example shown in FIG. 10. The substrate W is a semiconductor wafer in this example. A plurality of device formation areas 302 separated by trenches 301 are formed on the surface of the substrate W, and a gate 303 is formed in each of the device formation areas 302. FIGS. 11(a) to 11(c) illustrate a resist stripping and cleaning process of the substrate W carried out after the gate 303 is formed.

On a device formation surface Wa of the substrate W which has not been treated yet, for example, a resist 305 which has been used as a mask for dry etching for pattern formation of the gate 303 remains on the gate 303. A residue (a resist residue: a polymer) 306 such as a reaction product at the time of dry etching adheres to a sidewall of the gate 303 and the device formation surface Wa of the substrate W. Further, an electrostatic chuck trace (a contaminant) 307 at the time of dry etching adheres to a non-device formation surface Wb.

The substrate W which has not been treated yet is carried out of a cassette C by an indexer robot 22, and is transferred to the substrate carrying robot 11. At this time, the substrate W is in a horizontal posture where the device formation surface Wa is directed upward. The substrate W in this posture is carried into the chemical liquid treatment unit MP by the substrate carrying robot 11.

As shown in FIG. 11(a), in the treatment chamber 60 in the chemical liquid treatment unit MP, a resist stripping liquid 308 composed of an SPM solution is supplied to the surface of the substrate W from the movement nozzle 95 so that resist stripping treatment is performed. That is, the spin chuck 51 is rotated while the movement nozzle 95 is swung along the device formation surface Wa of the substrate W. Further, the sulfuric acid valve 88 and the hydrogen peroxide valve 89 are opened, so that the resist stripping liquid 308 is supplied to the movement nozzle 95. Consequently, resist stripping treatment progresses on the whole surface of the substrate W.

After the resist stripping treatment is performed for only a sufficient time period to remove the resist 305 on the gate 303, the supply of the resist stripping liquid 308 is stopped with the sulfuric acid valve 88 and the hydrogen peroxide valve 89 closed. Alternatively, the deionized water supply valve 90 is opened, to supply deionized water onto the substrate W and replace the resist stripping liquid on the substrate W. Thereafter, the deionized water supply valve 90 is closed, to make the movement nozzle 95 retreat toward the side of the spin chuck 51.

As shown in FIG. 11(b), in the treatment chamber 60 in the chemical liquid treatment unit MP, a jet 309 of droplets of a polymer removal liquid is then supplied to the surface of the substrate W by the two-fluid spray nozzle 100. That is, the polymer removal liquid (preferably, an inorganic liquid such as a dilute hydrofluoric acid solution) is supplied as a chemical liquid from the chemical liquid supply valve 115 to the two-fluid spray nozzle 100, and an inert gas is further supplied from the inert gas supply valve 117. On the other hand, at this time, the spin chuck 51 is rotated while the two-fluid spray nozzle 100 is swung back and forth in a range from the rotation center of the substrate W to the peripheral edge thereof. The range in which the two-fluid spray nozzle 100 swings may be a range from the peripheral edge of the substrate W to a peripheral edge on the opposite side of the substrate W through the rotation center of the substrate W (a range in which the nozzle crosses the substrate W through the rotation center).

By such treatment, the resist residue within the fine pattern on the substrate W is effectively removed simultaneously using the chemical action and the physical action by the jet of droplets of the polymer removal liquid. Moreover, within the same treatment chamber 60, the resist stripping treatment and the polymer removal treatment can be continuously performed with deionized water rinsing treatment interposed therebetween, thereby eliminating the necessity of drying the substrate W after the resist stripping treatment. Consequently, the polymer removal treatment can be efficiently performed, and a time period required for the whole of substrate treatment can be shortened. Further, the number of treatment chambers is reduced, thereby allowing the substrate treating apparatus to be miniaturized.

Because of the use of the SPM solution which is an inorganic acid chemical liquid in the resist stripping treatment, it is preferable that an inorganic polymer removal liquid is used as the polymer removal liquid. This allows the mixing of the inorganic chemical liquid and the organic chemical liquid to be restrained.

When the resist stripping treatment is terminated in the above-mentioned manner, the chemical liquid supply valve 115 and the inert gas supply valve 117 are closed to stop the supply of the polymer removal liquid to the two-fluid spray nozzle 100. Alternatively, the deionized water supply valve 116 is opened to supply the deionized water to the two-fluid spraynozzle 100. Consequently, the jet of droplets of the deionized water is supplied to the device formation surface Wa of the substrate W, so that the polymer removal liquid on the substrate W and the polymer residue separated from the substrate W are eliminated outward from the substrate W.

Thereafter, drying treatment for shaking down the droplets adhering to the substrate W is performed by closing the chemical liquid supply valve 115, making the two-fluid spray nozzle 100 retreat toward the side of the spin chuck 51, and rotating the spin chuck 51 at high speed. At this time, it is preferable that the shield plate 52 is lowered to a position in close proximity to the device formation surface Wa of the substrate W, and a nitrogen gas is supplied to the device formation surface Wa of the substrate W from the nitrogen gas supply passage 73, to perform the drying treatment of the substrate W in an inert gas atmosphere.

When the shield plate 52 is then introduced into the upper retreat position, and the rotation of the spin chuck 51 is stopped, so that the substrate W is carried out of the chemical liquid treatment unit MP by the substrate carrying robot 11. The substrate carrying robot 11 carries the substrate W into the substrate reversing unit 12. The substrate reversing unit 12 reverses the upper and lower surfaces of the carried substrate W. That is, the device formation surface Wa is a lower surface, and the non-device formation surface Wb is an upper surface. The substrate W in this posture is carried out of the substrate reversing unit 12 and is carried into the scrubbing unit SS by the substrate carrying robot 11.

In the scrubbing unit SS, the non-device formation surface Wb of the substrate W is scrubbed with the scrub brush 133, as shown in FIG. 11(c). That is, the spin chuck 130 is rotated, and the deionized water supply valve 141 is opened so that deionized water is supplied to the non-device formation surface Wb from an upper surface deionized water nozzle 136. In the state, the scrub brush 133 is lowered toward the rotation center of the substrate W so as to be brought into contact with the non-device formation surface Wb of the substrate W at predetermined contact pressure, and is then swung toward the peripheral edge of the substrate W. The scrub brush 133 is raised so as to be spaced apart from the non-device formation surface Wb when it reaches the peripheral edge of the substrate W, and is further moved upward from the rotation center of the substrate W. The scrub brush 133 is lowered toward the rotation center of the substrate W again. By repeating such operations, foreign matter on the non-device formation surface Wb of the substrate W (in this case, an electrostatic chuck trace 307) is discharged outward from the substrate W with the scrub brush 133.

In order to restrain the detour of the foreign matter toward the device formation surface Wa which is the lower surface of the substrate W, it is preferable that cover rinsing treatment for opening the deionized water supply valve 142 to supply the deionized water to the device formation surface Wa of the substrate W from a lower surface deionized water nozzle 137, and covering and protecting the device formation surface Wa by a liquid film 310 of the deionized water is concurrently performed.

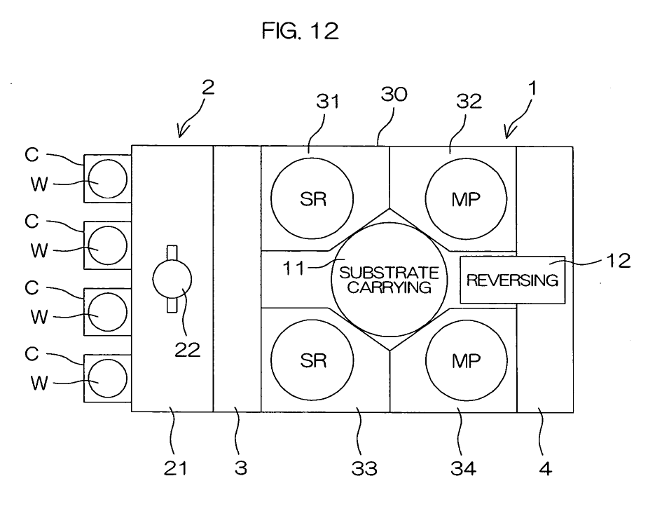

FIG. 12 is an illustrative plan view showing a second specific example of the configuration of the substrate treating apparatus. In the example of the configuration, two chemical liquid treatment units MP and two polymer removal units SR are respectively arranged in unit arrangement sections 31 to 34. That is, the two types of treatment units are mounted on a frame 30 and contained therein. More specifically, the two polymer removal units SR are respectively arranged in the unit arrangement sections 31 and 33 on the side of an indexer section 2, and the two chemical liquid treatment units MP are respectively arranged in the unit arrangement sections 32 and 34 farther from the indexer section 2. Although in the configuration shown in FIG. 12, a substrate reversing unit 12 is arranged at a position nearer to a treatment fluid box 4 between the two chemical liquid treatment units MP in the unit arrangement sections 32 and 34, the substrate reversing unit 12 need not be necessarily provided in treatment, described below.

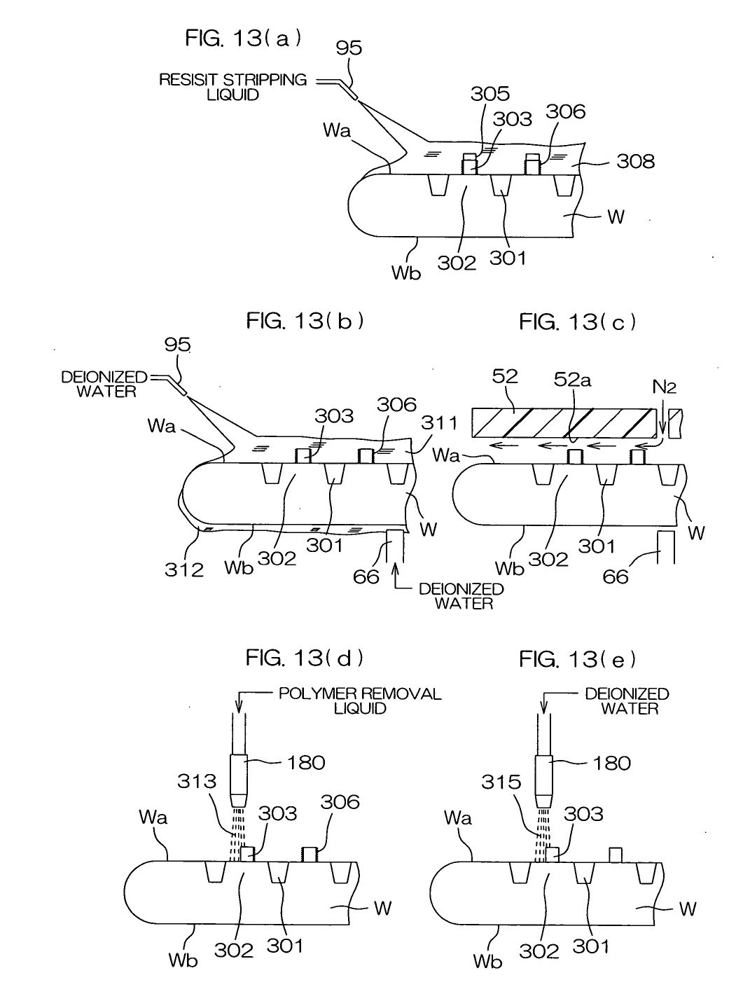

FIGS. 13(a) to 13(e) are illustrative sectional views showing the steps of a substrate treatment process by the substrate treating apparatus in the second specific example shown in FIG. 12. In FIGS. 13(a) to 13(e), the same sections as the above-mentioned sections shown in FIGS. 11(a) to 11(c) are assigned the same reference numerals as those shown in FIGS. 11(a) to 11(c). FIGS. 13(a) to 13(e) illustrate a resist stripping and cleaning process of the substrate W carried out after the gate 303 is formed.

The substrate W which has not been treated yet is carried out of a cassette C by an indexer robot 22, and is transferred to the substrate carrying robot 11. At this time, the substrate W is in a horizontal posture where the device formation surface Wa is directed upward. The substrate W in this posture is carried into the chemical liquid treatment unit MP by the substrate carrying robot 11.

As shown in FIG. 13(a), in the treatment chamber 60 in the chemical liquid treatment unit MP, a resist stripping liquid 308 composed of an SPM solution is supplied to the surface of the substrate W from the movement nozzle 95 so that resist stripping treatment is performed. That is, the spin chuck 51 is rotated, and the movement nozzle 95 is swung along the device formation surface Wa of the substrate W. Further, the sulfuric acid valve 88 and the hydrogen peroxide valve 89 are opened, so that the resist stripping liquid 308 is supplied to the movement nozzle 95. Consequently, resist stripping treatment progresses on the whole surface of the substrate W.

After the resist stripping treatment is performed for only a sufficient time period to remove a resist 305 on a gate 303, the supply of the resist stripping liquid 308 is stopped with the sulfuric acid valve 88 and the hydrogen peroxide valve 89 closed. Alternatively, the deionized water supply valve 90 is opened, to supply deionized water onto the substrate W and replace the resist stripping liquid on the substrate W. That is, as shown in FIG. 13(b), deionized water 311 is supplied to the device formation surface Wa (upper surface) of the substrate W from the movement nozzle 95, and the deionized water supply valve 68 is opened so that deionized water 312 is supplied to the non-device formation surface Wb (lower surface) of the substrate W from the lower surface nozzle 66. Consequently, both the surfaces of the substrate W are subjected to rinsing treatment.

Thereafter, the deionized water supply valves 90 and 68 are closed, so that the movement nozzle 95 is made to retreat toward the side of the spin chuck 51.

As shown in FIG. 13(c), the shield plate 52 is lowered to a position in close proximity to the device formation surface Wa of the substrate W, and the spin chuck 51 and the shield plate 52 are further synchronously rotated at the same high speed in the same direction. Further, a nitrogen gas is supplied between the device formation surface Wa and the substrate opposite surface 52 a of the shield plate 52 from the nitrogen gas supply passage 73. Consequently, the substrate W is subjected to spin drying treatment in an inert gas atmosphere.

The shield plate 52 is then introduced into the upper retreat position, and the rotation of the spin chuck 51 is stopped, so that the substrate W is carried out of the chemical liquid treatment unit MP by the substrate carrying robot 11. The substrate carrying robot 11 carries the substrate W into the polymer removal unit SR.

In the polymer removal unit SR, the substrate W is held in the spin chuck 160 with the device formation surface Wa taken as an upper surface. The spin chuck 160 is rotated, and the chemical liquid supply valve 186 and the inert gas supply valve 182 are opened. Consequently, as shown in FIG. 13(d), a polymer removal liquid serving as a chemical liquid and a nitrogen gas serving as an inert gas are mixed by the two-fluid spray nozzle 180, to form a mixed fluid, and a jet of droplets 313 of the polymer removal liquid contained in the mixed fluid is supplied to the device formation surface Wa of the substrate W. Consequently, the polymer 306 is efficiently removed by the multiplier effect of the chemical action of the polymer removal liquid and the physical action of the jet of droplets 313.

Thereafter, the chemical liquid supply valve 186 and the inert gas supply valve 182 are closed, and the deionized water supply valve 179 is opened instead, so that deionized water is supplied to the device formation surface Wa of the substrate W from the deionized water nozzle 162. Consequently, the polymer removal liquid on the device formation surface Wa is replaced with the deionized water.

The deionized water supply valve 179 is then closed, and the deionized water supply valve 187 and the inert gas supply valve 182 are opened instead. Thus, as shown in FIG. 13(e), physical cleaning treatment using a jet of droplets 315 of the deionized water produced from the two-fluid spray nozzle 180 is performed. In this state, the two-fluid spray nozzle 180 is swung back and forth in a range from the rotation center of the substrate W to the peripheral edge thereof. The range in which the two-fluid spray nozzle 180 swings may be a range from the peripheral edge of the substrate W to a peripheral edge on the opposite side of the substrate W through the rotation center of the substrate W (a range in which the nozzle crosses the substrate W through the rotation center).

Thereafter, drying treatment for shaking down the droplets adhering to the substrate W is performed by closing the deionized water supply valve 187 and the inert gas supply valve 182, making the two-fluid spray nozzle 180 retreat toward the side of the spin chuck 160, and rotating the spin chuck 160 at high speed.

The polymer removal unit SR may comprise a shield plate, similarly to the chemical liquid treatment unit MP. When the shield plate is provided, it is preferable that the shield plate is lowered to a position in close proximity to the device formation surface Wa of the substrate W, and the inert gas is supplied between the shield plate and the device formation surface Wa, to perform the drying treatment of the substrate W in an inert gas atmosphere.

When the drying treatment is terminated, the rotation of the spin chuck 160 is stopped, so that the substrate W is carried out of the polymer removal unit SR by the substrate carrying robot 11, is transferred to the indexer robot 22, and is accommodated in the cassette C.

In the present embodiment, the resist stripping treatment is thus performed within the treatment chamber 60 in the chemical liquid treatment unit MP, the substrate after the resist stripping treatment is carried into the polymer removal unit SR, and polymer removal treatment is performed within the treatment chamber 155. Therefore, a large amount of resist stripped from the substrate W by the resist stripping treatment in the chemical liquid treatment unit MP does not affect the subsequent polymer removal treatment. That is, when both the resist stripping treatment and the polymer removal treatment are performed within the treatment chamber 60, the large amount of resist produced in the resist stripping treatment adheres to an inner wall of the treatment chamber 60, and falls down during the polymer removal treatment and the subsequent spin drying treatment to adhere to the substrate W again, so that the substrate W may be contaminated again. This problem can be solved by the configuration of the present embodiment, so that the resist and the polymer can be precisely removed from the substrate W.

If a contaminant such as an electrostatic chuck trace on the side of the non-device formation surface Wb of the substrate W must be removed, an etchant (a cleaning liquid, e.g., a mixture of a hydrofluoric acid and a hydrogen peroxide solution) may be supplied toward the non-device formation surface Wb from the lower surface nozzle 66 in the chemical liquid treatment unit MP, for example.

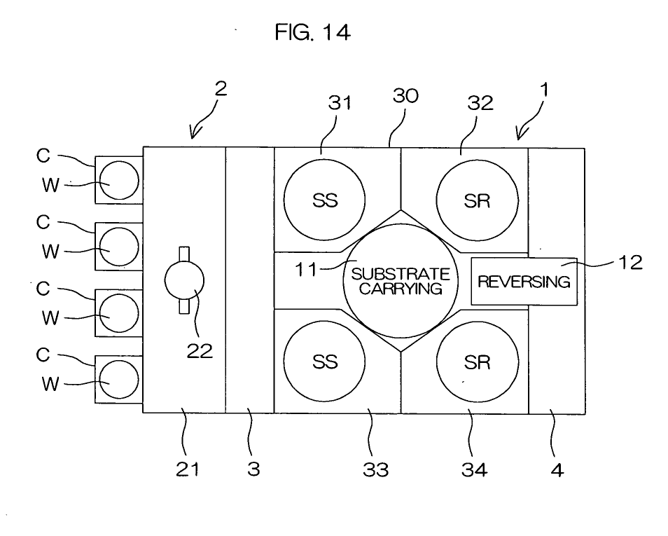

FIG. 14 is an illustrative plan view showing a third specific example of the configuration of the substrate treating apparatus. In the example of the configuration, two polymer removal units SR and two scrubbing units SS are respectively arranged in unit arrangement sections 31 to 34. That is, the two types of treatment units are mounted on a frame 30 and contained therein. More specifically, the two scrubbing units SS are respectively arranged in the unit arrangement sections 31 and 33 on the side of an indexer section 2, and the two polymer removal units SR are respectively arranged in the unit arrangement sections 32 and 34 farther from the indexer section 2. Further, a substrate reversing unit 12 for reversing the surface and the reverse surface of the substrate W carried from the treatment unit (here, the polymer removal unit SR) by the substrate carrying robot 11 is arranged at a position nearer to a treatment fluid box 4 between the two polymer removal units SR in the unit arrangement sections 32 and 34.

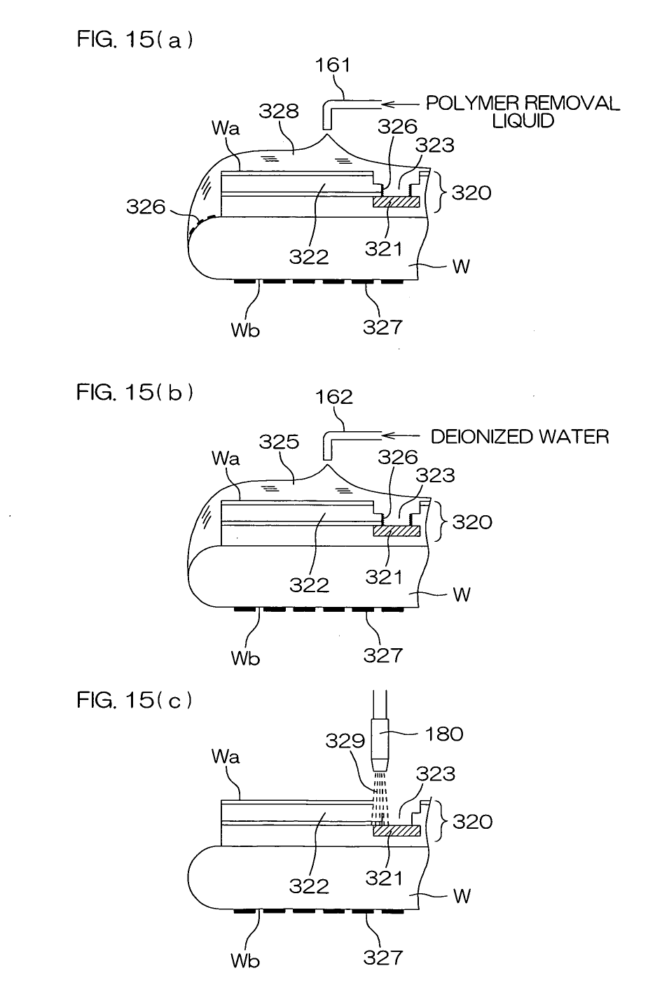

FIGS. 15(a), 15(b), and 15(c) are illustrative sectional views showing the steps of a substrate treatment process by the substrate treating apparatus in the third specific example shown in FIG. 14. The substrate W is a semiconductor wafer in this example. A semiconductor device is formed on the substrate W, and a multilayer wiring layer 320 is further formed thereon. The multilayer wiring layer 320 comprises a copper wiring 321 and a low dielectric-constant film (a so-called Low-k film having a lower dielectric constant than that of silicon oxide) 322 serving as an interlayer insulating film, for example. An aperture 323 for interlayer connection is formed at a predetermined position on the copper wiring 321. FIGS. 15(a), 15(b) and 15(c) illustrate a process for removing a resist residue 326 which remains on the substrate W after resist used as a mask in dry etching treatment for forming the aperture 323 is stripped. That is, the resist residue 326 remains on a device formation surface Wa of the substrate W. Further, an electrostatic chuck trace 327 serving as a contaminant from an electrostatic chuck used at the time of dry etching treatment adheres to a non-device formation surface Wb of the substrate W.

The substrate W which has not been treated yet is carried out of the cassette C by the indexer robot 22, and is transferred to the substrate carrying robot 11. At this time, the substrate W is in a horizontal posture where the device formation surface Wa is directed upward. The substrate W in this posture is carried into the polymer removal unit SR by the substrate carrying robot 11.

In the polymer removal unit SR, the substrate W is held in the spin chuck 160 with the device formation surface Wa taken as an upper surface. As shown in FIG. 15(a), the spin chuck 160 is rotated, and the chemical liquid supply valve 177 is opened, so that a polymer removal liquid 328 serving as a chemical liquid is supplied to the device formation surface Wa of the substrate W from the chemical liquid nozzle 161. Consequently, the polymer removal liquid 328 spreads throughout the whole area of the substrate W, so that a resist residue 326 is removed, or adhesion to the substrate W is weakened. The polymer removal liquid may be supplied from the two-fluid spray nozzle 180.

Thereafter, as shown in FIG. 15(b), the chemical liquid supply valve 177 is closed, and the deionized water supply valve 179 is opened instead, so that deionized water 325 is supplied to the device formation surface Wa of the substrate W from the deionized water nozzle 162. Consequently, the polymer removal liquid on the device formation surface Wa is replaced with the deionized water 325.

The deionized water supply valve 179 is then closed, so that physical cleaning treatment by the two-fluid spray nozzle 180 is performed, as shown in FIG. 15(c). That is, the deionized water supply valve 181 and the inert gas supply valve 182 are opened, so that a jet of droplets 329 of the deionized water is supplied toward the device formation surface Wa of the substrate W from the two-fluid spray nozzle 180. In this state, the two-fluid spray nozzle 180 is swung back and forth in a range from the rotation center of the substrate W to the peripheral edge thereof. The range in which the two-fluid spray nozzle 180 swings is a range from the peripheral edge of the substrate W to a peripheral edge on the opposite side of the substrate W through the rotation center of the substrate W (a range in which the nozzle crosses the substrate W through the rotation center).

In such a way, the resist residue 326 whose adhesion is weakened by the action of the polymer removal liquid is eliminated from the substrate W. Particularly, the resist residue 326 adhering to an inner wall of a microscopic aperture for interlayer connection 323 is difficult to remove only by the supply of the polymer removal liquid 328 from the chemical liquid nozzle 161 but can be effectively eliminated outward from the substrate W by physical cleaning treatment by the two-fluid spray nozzle 180.

Thereafter, drying treatment for shaking down the droplets adhering to the substrate W is performed by closing the deionized water supply valve 181 and the inert gas supply valve 182, making the two-fluid spray nozzle 180 retreat toward the side of the spin chuck 160, and rotating the spin chuck 160 at high speed.

The polymer removal unit SR may comprise a shield plate, similarly to the chemical liquid treatment unit MP. When the shield plate is provided, it is preferable that the shield plate is lowered to a position in close proximity to the device formation surface Wa of the substrate W, and an inert gas is supplied between the shield plate and the device formation surface Wa, to perform the drying treatment of the substrate W in an inert gas atmosphere.

When the drying treatment is terminated, the rotation of the spin chuck 160 is stopped, so that the substrate W is carried out of the polymer removal unit SR by the substrate carrying robot 11. The substrate carrying robot 11 carries the substrate W into the substrate reversing unit 12. The substrate reversing unit 12 reverses the upper and lower surfaces of the carried substrate W. That is, the device formation surface Wa is a lower surface, and the non-device formation surface Wb is an upper surface. The substrate W in this posture is carried out of the substrate reversing unit 12 and is carried into the scrubbing unit SS by the substrate carrying robot 11.

Treatment in the scrubbing unit SS is substantially the same as the above-mentioned treatment described with reference to FIG. 11(c) and hence, the description thereof is not repeated.

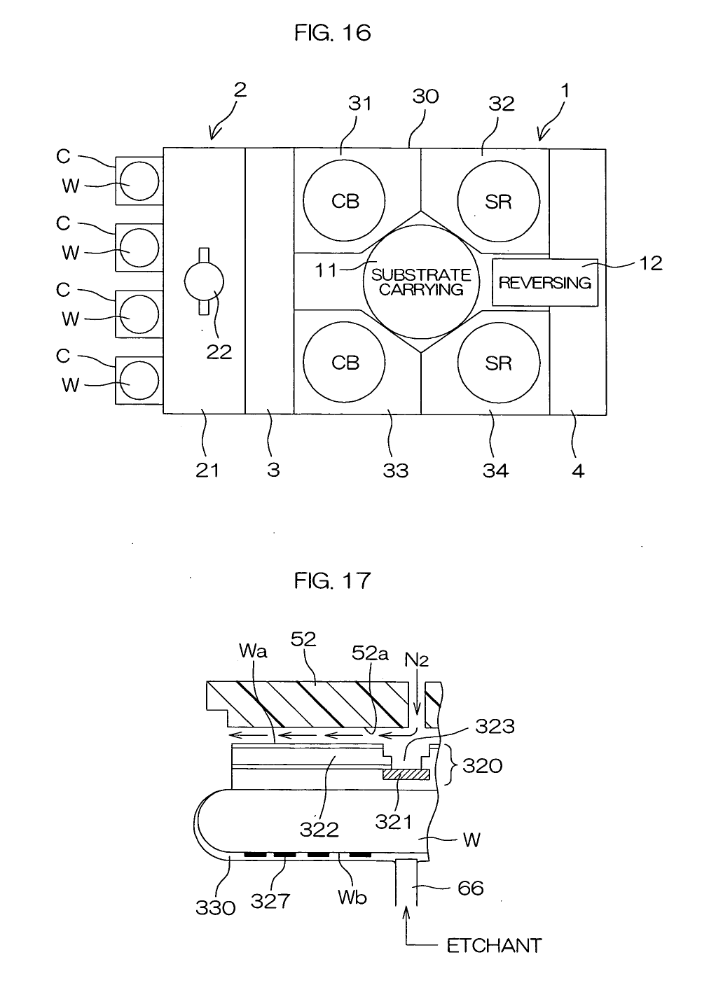

FIG. 16 is an illustrative plan view showing a fourth specific example of the configuration of the substrate treating apparatus. In the example of the configuration, two polymer removal units SR and two bevel cleaning units CB are respectively arranged in unit arrangement sections 31 to 34. That is, the two types of treatment units are mounted on a frame 30 and contained therein. More specifically, the two bevel cleaning units CB are respectively arranged in the unit arrangement sections 31 and 33 on the side of an indexer section 2, and the two polymer removal units SR are respectively arranged in the unit arrangement sections 32 and 34 farther from the indexer section 2.

In the substrate treating apparatus in the fourth specific example, treatment for the same purpose as that in the case of the apparatus in the third specific example is performed, and treatment in the polymer removal unit SR is as shown in FIGS. 15(a), 15(b), and 15(c), described above.

In the substrate treating apparatus in the forth specific example, the substrate W which has been treated in the polymer removal unit SR is carried out by the substrate carrying robot 11, and is carried into the bevel cleaning unit CB in a posture where the device formation surface Wa is directed upward (that is, without being reversed by the substrate reversing unit 12). That is, in the example of the configuration, the substrate reversing unit 12 need not be necessarily provided.

FIG. 17 is an illustrative sectional view for explaining the treatment in the bevel cleaning unit CB. In FIG. 17, the same sections as the above-mentioned sections shown in FIGS. 15(a), 15(b), and 15(c) are assigned the same reference numerals as those shown in FIGS. 15(a) to 15(c). The substrate W is held in the spin chuck 51 and rotated with the device formation surface Wa directed upward. The shield plate 52 is brought nearer to the device formation surface Wa of the substrate W, and is synchronously rotated at the same speed in the same direction as the spin chuck 51. Correspondingly, a nitrogen gas is blown off between the device formation surface Wa and the substrate opposite surface 52a of the shield plate 52 from the nitrogen gas supply passage 73.

On the other hand, the chemical liquid supply valve 67 is opened, so that an etchant (a cleaning liquid: e.g., a mixture of a hydrofluoric acid and a hydrogen peroxide solution) 330 serving as a chemical liquid is supplied to the center of the non-device formation surface Wa of the substrate W from the lower surface nozzle 66. The etchant 330 expands radially outward in the rotation through the non-device formation surface Wb of the substrate W, to treat the whole area of the non-device formation surface Wb, and further leads to the peripheral edge of the device formation surface Wa of the substrate W through the peripheral end surface of the substrate W, to also treat the areas. Consequently, foreign matter (an electrostatic chuck trace 327 ) adhering to the non-device formation surface Wb is eliminated.

While the substrate W is being rotated, the whole area of the peripheral end surface of the substrate W can be cleaned throughout by varying a position to be interposed by the clamp member 64, as described above.

When the chemical liquid supply valve 67 is then closed to stop the supply of the etchant, the deionized water supply valve 68 is opened, so that the deionized water is discharged from the lower surface nozzle 66. Consequently, the etchant is eliminated from the non-device formation surface Wb, the peripheral end surface, and the peripheral edge of the device formation surface Wa of the substrate W. At this time, the deionized water may be also discharged from the treatment liquid nozzle 72, to concurrently subject the device formation surface Wa of the substrate W to deionized water rinsing treatment.

Thereafter, drying treatment for shaking down the droplets on the substrate W and dry the substrate W is performed by closing the deionized water supply valve 68 to stop the supply of the deionized water to the substrate W and rotating the spin chuck 51 at high speed. At this time, the shield plate 52 is held at a position in close proximity to the device formation surface Wa of the substrate W, to prevent the droplets from adhering due to rebound.

As in the treatment shown in FIGS. 15(a), 15(b) and 15(c) and FIG. 17, it is preferable that after the substrate W having a low dielectric-constant film 322 formed therein is subjected to treatment using the treatment liquid, the substrate W is subjected to reduced-pressure drying treatment. The reason for this is that many of Low-k materials are generally porous and hygroscopic, and the dielectric constant thereof may be varied by taking in a gas at the time of etching and ashing, thereby causing the possibility of degrading device characteristics. The liquid and the gas which have entered into the inside of the material are difficult to remove only by spin drying treatment.

Therefore, in the substrate treating apparatus according to the present embodiment, a unit arrangement section (not shown) for arranging a reduced-pressure heating and drying unit is provided above the unit arrangement sections 31 to 34. The reduced-pressure drying unit comprises a hot plate for heating the substrate W, a heat treatment chamber accommodating the hot plate, and an exhaust mechanism for evacuating the heat treatment chamber to reduce pressure. The substrate W is dried while simultaneously performing heating and pressure reduction by such a reduced-pressure heating and drying unit to evaporate and eliminate a residue (particularly, a liquid) entering a porous structure, thereby allowing the dielectric constant of the low dielectric-constant film 322 to be maintained.

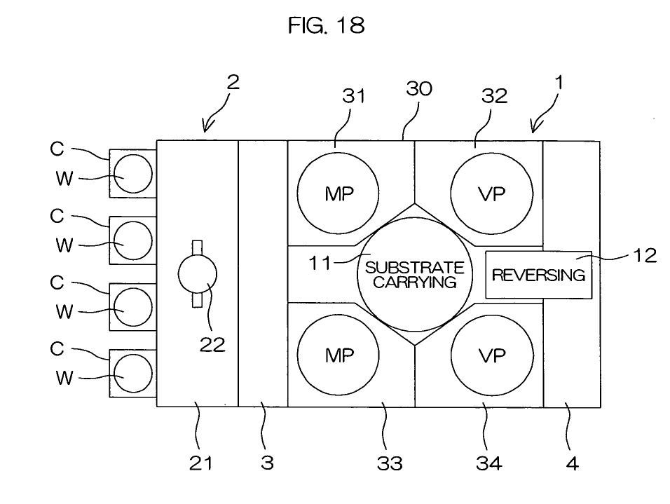

FIG. 18 is an illustrative plan view showing a fifth specific example of the configuration of the substrate treating apparatus. In the example of the configuration, two chemical liquid treatment units MP and two vapor phase cleaning units VP are respectively arranged in unit arrangement sections 31 to 34. That is, the two types of treatment units are mounted on a frame 30 and carried therein. More specifically, the two chemical liquid treatment units MP are respectively arranged in the unit arrangement sections 31 and 33 on the side of an indexer section 2, and the two gas phase cleaning units VP are respectively arranged in the unit arrangement sections 32 and 34 farther from the indexer section 2.

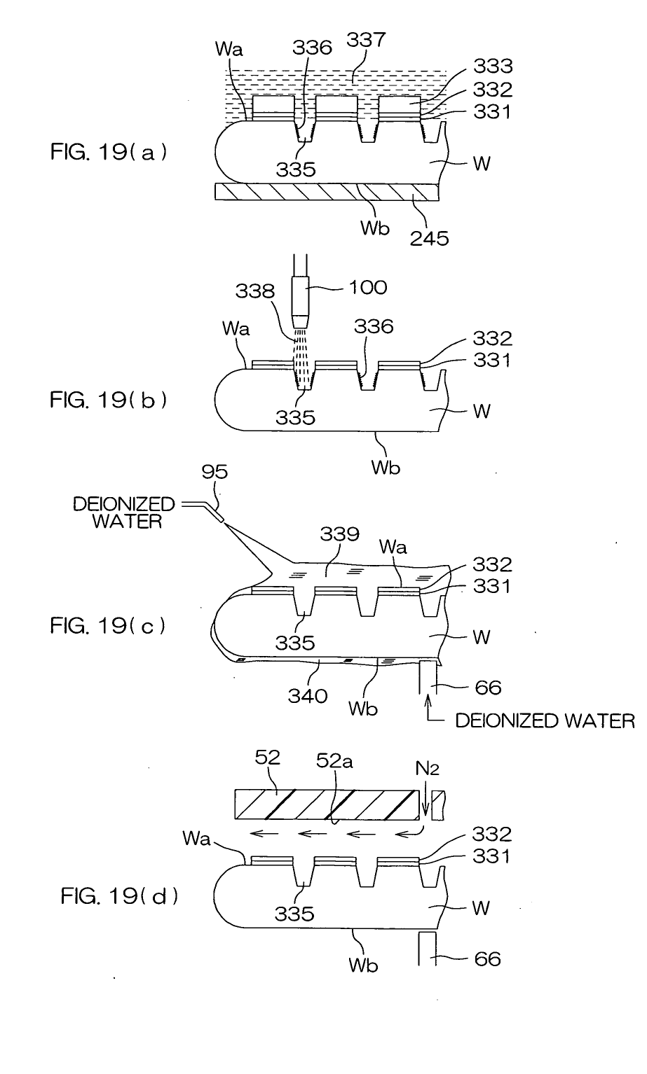

FIGS. 19(a) to 19(d) are illustrative sectional views showing the steps of a substrate treatment process by the substrate treating apparatus in the fifth specific example shown in FIG. 18. The substrate W is a semiconductor wafer in this example. A gate oxide film 331, a nitride film 332, and a BPSG film 333 are stacked and formed on a device formation surface Wa of the substrate W. After the films are stacked and formed on the whole surface of the substrate W, a resist pattern is formed on the BPSG film 333, and the BPSG film 333 is patterned, as shown in FIG. 19(a), by the resist pattern. Dry etching treatment is performed using the patterned BPSG film 333 as a mask, so that the nitride film 332 and the gate oxide film 331 are patterned, and trenches for device separation 335 are formed on the substrate W. A reaction product 336 at the time of dry etching also exists on the substrate W. Treatment shown in FIGS. 19(a) to 19(d) is a selective etching process for selectively removing the BPSG film 333 and the reaction product 336 from the substrate W while restraining the effect on the gate oxide film 331 (particularly, side etching) to a minimum.

The substrate W which has not been treated yet is carried out of the cassette C by the indexer robot 22, and is transferred to the substrate carrying robot 11. At this time, the substrate W is in a horizontal posture where the device formation surface Wa is directed upward. The substrate W in this posture is carried into the vapor phase cleaning unit VP by the substrate carrying robot 11.

In the gas phase cleaning unit VP, the substrate W is placed on a hot plate 245 with the device formation surface Wa directed upward, and a vapor 337 including a hydrofluoric acid is supplied to the substrate W in a state where the substrate W is heated, as shown in FIG. 19(a). The hot plate 245 is controlled to adjust the temperature of the substrate W to a temperature at which a high etching selection ratio (e.g., 1000:1) of the BPSG film 333 to the gate oxide film 331 is obtained, thereby making it possible to remove the BPSG film 333 while restraining damage to the gate oxide film 331 (particularly, side etching) to a minimum.

After selective etching treatment using a hydrofluoric acid vapor is performed until the BPSG film 333 is completely removed, the substrate carrying robot 11 carries the substrate W out of the gas phase cleaning unit VP, and carries the substrate W into the chemical liquid treatment unit MP without changing the posture (that is, without being reversed by the substrate reversing unit 12). In the chemical liquid treatment unit MP, treatment for removing the reaction product 336 (particularly, one within the trench 335) which cannot be completely removed by the selective etching treatment using the hydrofluoric acid vapor is performed.

As shown in FIG. 19(b), in the chemical liquid treatment unit MP, physical cleaning treatment using the two-fluid spray nozzle 100 is first performed. At this time, deionized water from the deionized water supply valve 116 and an inert gas from the inert gas supply valve 117 are supplied to the two-fluid spray nozzle 100. Consequently, the two-fluid spray nozzle 100 supplies a jet of droplets 338 of the deionized water toward the device formation surface Wa of the substrate W. At this time, the spin chuck 51 which holds the substrate W is rotated, and the two-fluid spray nozzle 100 is swung so as to move back and forth between the rotation center of the substrate W and the peripheral edge thereof. The range in which the two-fluid spray nozzle 100 swings may be a range from the peripheral edge of the substrate W to a peripheral edge on the opposite side of the substrate W through the rotation center of the substrate W (a range in which the nozzle crosses the substrate W through the rotation center).

By a physical force due to the jet of droplets of the deionized water, a reaction product 336 adhering to the device formation surface Wa of the substrate W (particularly, an inner wall of the trench 335) is detached from the substrate W and is eliminated outward from the substrate W.

Thereafter, the deionized water supply valve 116 and the inert gas supply valve 117 are closed, to make the two-fluid spray nozzle 100 retreat toward the side of the spin chuck 51, and the substrate W is then subjected to deionized water cleaning treatment.

That is, as shown in FIG. 19(c), the deionized water supply valve 90 is opened so that a deionized water 339 is supplied to the device formation surface Wa (upper surface) of the substrate W from the movement nozzle 95, and the deionized water supply valve 68 is further opened so that a deionized water 340 is supplied to a non-device formation surface Wb (lower surface) of the substrate W from the lower surface nozzle 66. Consequently, both the surfaces of the substrate W is subjected to rinsing treatment.

Thereafter, the deionized water supply valves 90 and 68 are closed, so that the movement nozzle 95 is made to retreat toward the side of the spin chuck 51.

As shown in FIG. 19(d), the shield plate 52 is lowered to a position in close proximity to the device formation surface Wa of the substrate W, and the spin chuck 51 and the shield plate 52 are further synchronously rotated at the same high speed in the same direction. Further, a nitrogen gas is supplied between the device formation surface Wa and the substrate opposite surface 52a of the shield plate 52 from the nitrogen gas supply passage 73. Thus, the substrate W is subjected to spin drying treatment in an inert gas atmosphere.

The gate oxide film 331, the nitride film 332, and the surface of the substrate W itself are exposed to the device formation surface Wa of the substrate W, so that there occur situations where a water mark is easily produced because hydrophilic and hydrophobic portions are mixed. Even under such situations, such good drying treatment that no water mark is produced is allowed by spin drying under an inert gas atmosphere.

After the gas phase cleaning treatment shown in FIG. 19(a), the deionized water cleaning treatment shown in FIG. 19(c) may be further added before the physical cleaning treatment by the two-fluid spray nozzle 100 shown in FIG. 19(b). In such a way, the gas phase cleaning treatment in FIG. 19(a) can be quickly stopped by the deionized water cleaning treatment, so that the gas phase cleaning treatment can be uniformly performed within the device formation surface Wa.

Although description has been made of the embodiment of the present invention, the present invention can be also embodied by another embodiment. For example, a combination of treatment units incorporated in the unit arrangement sections 31 to 34 may be one other than the foregoing. An arbitrary combination can be employed in a range of a combination of treatments which can be implemented by each of the treatment units. The treatments which can be implemented by the treatment units are together shown in the following Table 1.

TABLE 1

| Type of Treatment | | MP | SS | SR | CB | VP |
|---|---|---|---|---|---|---|
| FEOL | Cleaning before film | ∘ | ∘ | | | |
| | formation/ | | | | | |
| | before diffusion | | | | | |
| | Cleaning after | ∘ | ∘ | | | |
| | film formation | | | | | |
| | Cleaning after CMP | ∘ | ∘ | | | |
| | Cleaning after | ∘ | ∘ | ∘ | | |
| | etching | | | | | |
| | Cleaning after ashing | ∘ | ∘ | ∘ | | |
| | High-precision | ∘ | | | | ∘ |
| | etching | | | | | |
| | Reverse surface/ | | ∘ | | ∘ | |
| | bevel cleaning | | | | | |
| | Reverse surface | | | | ∘ | |
| | etching | | | | | |
| | Wafer reproduction | ∘ | | | | |
| | Resist stripping | ∘ | | ∘ | | |
| | Selective etching | | | | | ∘ |
| BEOL | Cleaning after film | ∘ | ∘ | | | |
| | formation | | | | | |
| | Cleaning after CMP | ∘ | ∘ | | | |
| | Cleaning after | ∘ | ∘ | ∘ | | |
| | etching | | | | | |
| | Cleaning after ashing | ∘ | ∘ | ∘ | | |
| | Reverse surface/ | | ∘ | | ∘ | |
| | bevel cleaning | | | | | |
| | Reverse surface | | | | ∘ | |
| | etching | | | | | |
| | Wafer reproduction | ∘ | | | | |
| | Resist stripping | ∘ | | ∘ | | |

In Table 1, FEOL (Front End of the Line) indicates a preliminary process (a process before metal wiring of the first layer) in a semiconductor fabrication process. BEOL (Back End of the Line) indicates a process for forming multilayer wiring after the preliminary process. For example, reverse surface etching in the FEOL is treatment for selectively removing, when a polysilicon film and a nitride silicon film are formed by a CVD (Chemical Vapor Deposition) method, the films adhering to a non-device formation surface (reverse surface). On the other hand, reverse surface etching in the BEOL is treatment for selectively removing, after a copper thin film for wiring is formed, for example, an unnecessary copper thin film adhering to a non-device formation surface (reverse surface).

The cleaning treatment before film formation is cleaning before film formation on the substrate W, and cleaning treatment before diffusion is cleaning before heat treatment for diffusing impurity ions implanted into the substrate W. Chemical liquids such as a hydrofluoric acid, SC1 (a mixture of ammonia and a hydrogen peroxide solution), and SC2 (a mixture of a sulfuric acid and a hydrogen peroxide solution), for example, are used for the cleaning treatment.

CMP indicates chemical mechanical polishing treatment. Further, high-precision etching represents etching treatment requiring high-precision in-plane uniformity, for example, etching of a gate oxide film. Wafer reproduction indicates treatment for stripping a structure formed on a surface and reusing a semiconductor wafer when problems such as a wiring mistake occur.

Furthermore, although in the above-mentioned embodiment, description has been made of a case where two types of treatment units are used, three types of treatment units, for example, a polymer removal unit SR, a bevel cleaning unit CB, and a scrubbing unit SS may be combined. The treatment in this case may be treatment for removing a resist residue on a device formation surface of a substrate W in the polymer removal unit SR, then removing a metal contaminate on a non-device formation surface and a peripheral end surface of the substrate W in the bevel cleaning unit CB, then reversing the upper and lower surfaces of the substrate W by a substrate reversing unit 12, and then subjecting a non-device formation surface of the substrate W to scrubbing in the scrubbing unit SS. Of course, the four types of treatment units may be combined. Alternatively, if five unit arrangement sections are provided within the frame 30, combinations of five types of treatment units are also possible.

Although in the above-mentioned embodiment, description has been made of a case where the four unit arrangement sections 31 to 34 are provided in the frame 30, at least two unit arrangement sections may be provided. Other than that, the number of unit arrangement sections is not limited.

Although the present invention has been described and illustrated in detail, it is clearly understood that the same is by way of illustration and example only and is not to be taken by way of limitation, the spirit and scope of the present invention being limited only by the terms of the appended claims.

The present application corresponds to Japanese Patent Applications No. 2003-403575 filed with the Japanese Patent Office on Dec. 2, 2003 and No. 2004-93487 filed with the Japanese Patent Office on Mar. 26, 2004, the disclosures of which are hereinto incorporated by reference.

1. A substrate treating apparatus comprising:
at least two types of treatment units selected from the group consisting of a chemical liquid treatment unit for holding and rotating a substrate by a substrate holding and rotating mechanism as well as supplying a chemical liquid from a chemical liquid nozzle to the substrate to treat the substrate, a scrubbing unit for holding and rotating a substrate by a substrate holding and rotating mechanism to supply deionized water to the substrate as well as scrubbing a surface of the substrate with a scrub brush, a polymer removal unit for holding and rotating a substrate by a substrate holding and rotating mechanism as well as supplying a polymer removal liquid to the substrate to remove a residue on the substrate, a peripheral end surface treatment unit for holding and rotating a substrate by a substrate holding and rotating mechanism as well as supplying a treatment liquid to an area including the whole of one surface and a peripheral end surface of the substrate so as to selectively remove an unnecessary material in the area, and a gas phase treatment unit for supplying a vapor including a chemical liquid or a vapor including a chemical gas to a substrate held in a substrate holding mechanism to treat the substrate; and
a substrate carrying mechanism for carrying a substrate into/out of at least the two types of treatment units.

2. The substrate treating apparatus according to claim 1, further comprising
a reversing unit for reversing the front and back surfaces of the substrate carried by the substrate carrying mechanism from one of at least the two types of treatment units.

3. The substrate treating apparatus according to claim 2, wherein
at least the two types of treatment units include the scrubbing unit, and
the scrubbing unit scrubs the surface of the substrate which has been reversed by the reversing unit.

4. The substrate treating apparatus according to claim 1, wherein
at least the two types of treatment units includes the chemical liquid treatment unit and the scrubbing unit.

5. The substrate treating apparatus according to claim 1, wherein
at least the two types of treatment units includes the chemical liquid treatment unit and the polymer removal unit.

6. The substrate treating apparatus according to claim 5, wherein
the chemical liquid nozzle in the chemical liquid treatment unit includes a nozzle for supplying a resist stripping liquid for stripping the resist film on the surface of the substrate which is held by the substrate holding and rotating mechanism.

7. The substrate treating apparatus according to claim 1, wherein
at least the two types of treatment units include the scrubbing unit and the polymer removal unit.

8. The substrate treating apparatus according to claim 1, wherein
at least the two types of treatment units include the polymer removal unit and the peripheral end surface treatment unit.

9. The substrate treating apparatus according to claim 1, wherein
at least the two types of treatment units include the chemical liquid treatment unit and the gas phase treatment unit.

10. The substrate treating apparatus according to claim 9, wherein
the chemical liquid treatment unit further includes a droplet jet supply section for supplying a jet of droplets of the treatment liquid to the substrate held in the substrate holding and rotating mechanism.

11. A substrate treating method comprising at least two steps selected from the group consisting of:
a chemical liquid treating step for supplying a chemical liquid to a substrate which is held and rotated by a substrate holding and rotating mechanism to treat the substrate;
a scrubbing step for supplying deionized water to a substrate which is held and rotated by a substrate holding and rotating mechanism as well as scrubbing a surface of the substrate with a scrub brush to remove foreign matter on the surface of the substrate;
a polymer removing step for supplying a polymer removal liquid to a substrate which is held and rotated by a substrate holding and rotating mechanism, to remove a residue on the substrate;
a peripheral end surface treating step for supplying a treatment liquid to an area including the whole of one of surfaces and a peripheral end surface of the substrate which is held and rotated by a substrate holding and rotating mechanism, to selectively remove an unnecessary material in the area;
a gas phase treating step for supplying a vapor including a chemical liquid or a vapor including a chemical gas to a substrate held in a substrate holding mechanism to treat the substrate.

12. The substrate treating method according to claim 11, wherein
at least the two steps are continuously carried out through a substrate carrying step for carrying the substrate without accommodating the substrate in an accommodation chamber capable of accommodating a plurality of substrates.

13. The substrate treating method according to claim 11, further comprising
a reversing step for reversing the front and back surfaces of the substrate between at least the two steps.

14. The substrate treating method according to claim 12, further comprising
a reversing step for reversing the front and back surfaces of the substrate between at least the two steps.

15. The substrate treating method according to claim 13, wherein
the scrubbing step is carried out after the reversing step, to subject a non-device formation surface which is opposite to a device formation surface of the substrate to scrubbing treatment.

16. The substrate treating method according to claim 14, wherein
the scrubbing step is carried out after the reversing step, to subject a non-device formation surface which is opposite to a device formation surface of the substrate to scrubbing treatment.

17. The substrate treating method according to claim 11, wherein
at least the two steps include the chemical liquid treating step and the scrubbing step,
the device formation surface of the substrate is subjected to chemical liquid treatment in the chemical liquid treating step, and
a non-device formation surface which is opposite to the device formation surface of the substrate is subjected to scrubbing treatment in the scrubbing step.

18. The substrate treating method according to claim 11, wherein
at least the two steps include the chemical liquid treating step and the polymer removing step,
a chemical liquid is supplied to the device formation surface of the substrate to perform chemical liquid treatment in the chemical liquid treating step, and
the device formation surface of the substrate is subjected to polymer removal treatment in the polymer removing step.

19. The substrate treating method according to claim 18, wherein
the chemical liquid treating step includes the step of supplying a resist stripping liquid as the chemical liquid to the device formation surface of the substrate, to strip the resist film on the device formation surface.

20. The substrate treating method according to claim 11, wherein
at least the two steps include the scrubbing step and the polymer removing step,
the device formation surface of the substrate is subjected to polymer residue removal treatment in the polymer removing step, and
a non-device formation surface which is opposite to the device formation surface of the substrate is subjected to scrubbing treatment in the scrubbing step.

21. The substrate treating method according to claim 11, wherein
at least the two steps include the polymer removing step and the peripheral end surface treating step,
the device formation surface of the substrate is subjected to polymer removal treatment in the polymer removing step, and
unnecessary materials on a non-device formation surface which is opposite to the device formation surface and a peripheral end surface of the substrate are selectively removed in the peripheral end surface treating step.

22. The substrate treating method according to claim 11, wherein
at least the two steps include the gas phase treating step and the chemical liquid treating step,
a thin film on the device formation surface of the substrate is selectively etched in the gas phase treating step, and
the device formation surface of the substrate is subjected to chemical liquid treatment in the chemical liquid treating step.

23. The substrate treating method according to claim 22, wherein
a jet of droplets of the treatment liquid is supplied to the device formation surface in the chemical liquid treating step.

24. A substrate treating apparatus comprising:
a substrate holding and rotating mechanism for holding and rotating a substrate;
a resist stripping liquid nozzle for supplying a resist stripping liquid to a substrate to be treated which is held and rotated by the substrate holding and rotating mechanism; and
a polymer removal liquid nozzle for supplying a polymer removal liquid to a substrate to be treated which is held and rotated by the substrate holding and rotating mechanism.

25. The substrate treating apparatus according to claim 24, wherein
the polymer removal liquid nozzle supplies an inorganic polymer removal liquid.

26. A substrate treating method comprising:
a substrate holding and rotating step for holding and rotating a substrate by a substrate holding and rotating mechanism arranged in a treatment chamber,
a resist stripping step for supplying a resist stripping liquid to the surface of the substrate which is held and rotated in the substrate holding and rotating step, to strip a resist film-on the substrate, and
a polymer removing step for supplying a polymer removal liquid to a surface of the substrate which is held in the substrate holding and rotating step after the resist stripping step.

27. The substrate treating method according to claim 26, wherein
the polymer removing step comprises the step of supplying an inorganic polymer removal liquid to the substrate.
